(19) United States
(12) Patent Application Publication
(10) Pub. No.: US 2025/0072216 A1
(43) Pub. Date: Feb. 27, 2025

(54) DISPLAY PANEL, MANUFACTURING METHOD THEREOF, AND HEAD-MOUNTED DISPLAY DEVICE INCLUDING THE SAME

(71) Applicant: Samsung Display Co., Ltd., Yongin-Si (KR)

(72) Inventors: Jun Hyuk WOO, Yongin-si (KR); Rae Young KIM, Yongin-si (KR); Ree Hyang KIM, Yongin-si (KR); Jong Min OK, Yongin-si (KR); Je Won YOO, Yongin-si (KR)

(21) Appl. No.: 18/648,759

(22) Filed: Apr. 29, 2024

(30) Foreign Application Priority Data
Aug. 23, 2023 (KR) 10-2023-0110851

(51) Int. Cl. H10K 59/121; G02B 27/01; H10K 59/12; H10K 59/38; H10K 59/80

(52) U.S. Cl. CPC H10K 59/1213; G02B 27/0172; H10K 59/1201; H10K 59/1216; H10K 59/38; H10K 59/879

(57) ABSTRACT

Embodiments of the present disclosure provide a display panel including: an overcoat layer disposed on a light emitting element layer and having a first refractive index; and a cover window disposed on the overcoat layer and having a second refractive index greater than the first refractive index, wherein at least one of the overcoat layer and the cover window includes a plurality of inclined surfaces, and inclination angles of the plurality of inclined surfaces in a central area are different from those in an edge area. The display panel, the manufacturing method thereof, and the head-mounted display device including the same according to the embodiments of the present disclosure May control the angle of emitted light.

### CROSS-REFERENCE TO RELATED APPLICATION

This application claims priority to and the benefit of Korean Patent Application No. 10-2023-0110851 filed in the Korean Intellectual Property Office on Aug. 23, 2023, the entire contents of which are incorporated herein by reference.

### BACKGROUND

### (a) Field

Embodiments of the present disclosure relate to a display panel, a manufacturing method thereof, and a head-mounted display device including the same.

### (b) Description of the Related Art

As information technology has developed, importance of a display device, which is a connection medium between a user and information, has been highlighted. Accordingly, the use of display devices such as a liquid crystal display device, an organic light emitting display device, and the like has been increasing.

As the display device displays an image in an area close to the user's eyes, various research is being conducted on technologies for controlling the angle at which light is emitted from the display device (or a display panel of the display device).

### SUMMARY

The present disclosure has been made in an effort to provide a display panel in which the angle of emitted light is controlled, a manufacturing method thereof, and a head-mounted display device including the same.

Embodiments of the present disclosure provide a display panel including: a substrate; a pixel circuit layer disposed on the substrate and including at least one switching element and at least one storage element; a light emitting element layer including a plurality of light emitting elements electrically connected to the pixel circuit layer and disposed on the pixel circuit layer; an overcoat layer disposed on the light emitting element layer and having a first refractive index; and a cover window disposed on the overcoat layer and having a second refractive index greater than the first refractive index, wherein at least one of the overcoat layer and the cover window includes a plurality of inclined surfaces, and inclination angles of the plurality of inclined surfaces in a central area are different from those in an edge area.

An inclination angle in the central area may be smallest and an inclination angle in the edge area is largest.

Light emitted from a light emitting element in the central area may be emitted in a normal direction to the substrate, and light emitted from t a light emitting element in the edge area may be emitted in an outer direction of the substrate to form a predetermined angle with the normal direction of the substrate.

The overcoat layer may include a plurality of inclined surfaces. The plurality of inclined surfaces may increase in height from the outside to the inside of the substrate.

The cover window may include a plurality of inclined surfaces. Heights of the plurality of inclined surfaces may increase as distances from the central area increase.

Each of the plurality of inclined surfaces may be disposed in an area corresponding to one light emitting element.

A light emitting element layer may include at least two light emitting elements, and each of the plurality of inclined surfaces may be disposed in an area corresponding to the at least two light emitting elements.

Some of the plurality of inclined surfaces may be shifted from corresponding light emitting elements in an outer direction of the substrate.

The display panel may further include an optical functional layer disposed between the light emitting element layer and the overcoat layer. The optical functional layer may include a color filter layer including a color filter configured to filter a wavelength band of light emitted from the light emitting element; and a lens array including a plurality of lenses. The optical functional layer may be shifted from the corresponding light emitting elements in the outer direction of the substrate.

The overcoat layer may include an epoxy resin whose refractive index is the first refractive index, and the cover window may include glass whose refractive index is the second refractive index. The first refractive index may be 1.2 to 1.4 and the second refractive index may be 1.5 to 1.9.

Embodiment of the present disclosure provide a manufacturing method of a display panel, including: preparing a lower substrate; forming an overcoat layer on the lower substrate; pressing the lower substrate on which the overcoat layer is formed with a stamp including a plurality of inclined surface molds; detaching the stamp from the lower substrate; and forming a cover window on the overcoat layer.

The stamp may press an upper surface of the overcoat layer in the pressing with the stamp, and a plurality of inclined surfaces may be formed on the overcoat layer in the pressing with the stamp.

Glass having a lower surface with a plurality of inclined surfaces corresponding to the plurality of inclined surfaces of the overcoat layer may be disposed on the overcoat layer in the forming of the cover window.

The manufacturing method of the display panel may further include applying a photoresist on the overcoat layer. The stamp may press the applied photoresist in the pressing with the stamp, and a plurality of inclined surfaces corresponding to the plurality of inclined surface molds may be formed in the photoresist.

The manufacturing method of the display panel may further include etching the photoresist and the overcoat layer on which the plurality of inclined surfaces are formed. The plurality of inclined surfaces may be formed on the overcoat layer in the etching of the photoresist and the overcoat layer.

A pixel circuit layer, a light emitting element layer, a thin film encapsulation layer, an adhesive layer, a color filter layer, and a lens array may be sequentially formed on the lower substrate in the preparing of the lower substrate.

Embodiment of the present disclosure provide a head-mounted display device, including: a first display panel disposed in a display device accommodation case and having a protective layer disposed on an uppermost layer of the first display panel and including a plurality of inclined surfaces; a right eye lens disposed in the display device accommodation case and configured to refract light refracted on the plurality of inclined surfaces of the first display panel to be directed to a right eye of a user; a second display panel disposed in the display device accommodation case to be spaced apart from the first display panel and having a protective layer disposed on an uppermost layer of the second display panel and including a plurality of inclined surfaces; and a left eye lens disposed in the display device accommodation case and configured to refract light refracted on the plurality of inclined surfaces of the second display panel to be directed to a left eye of the user.

Light emitted from a central area of the first display panel may be incident in a central area of the right eye lens, and light emitted from an edge area of the first display panel may be incident in an edge area of the right eye lens; and light emitted from a central area of the second display panel may be incident in a central area of the left eye lens, and light emitted from an edge area of the second display panel may be incident in an edge area of the left eye lens.

Each of the first display panel and the second display panel may include a substrate; a pixel circuit layer disposed on the substrate and including at least one switching element and at least one storage element; a light emitting element layer including a plurality of light emitting elements electrically connected to the pixel circuit layer and disposed on the pixel circuit layer; an overcoat layer disposed on the light emitting element layer and having a first refractive index; and a cover window disposed on the overcoat layer and having a second refractive index greater than the first refractive index, and at least one of the overcoat layer and the cover window may include a plurality of inclined surfaces, and inclination angles of the plurality of inclined surfaces in a central area may be different from those in an edge area.

The inclination angles of the plurality of inclined surfaces may increase as distances from the central area increase.

The display panel, the manufacturing method thereof, and the head-mounted display device including the same according to the embodiments of the present disclosure, it is possible to control the angle of emitted light.

### BRIEF DESCRIPTION OF THE DRAWINGS

FIG. 1 illustrates a system block diagram of a display device according to embodiments of the present disclosure.

FIG. 2 illustrates a block diagram of an example of one of sub-pixels of FIG. 1.

FIG. 3 illustrates an equivalent circuit of an example of the sub-pixel of FIG. 2.

FIG. 4 illustrates a top plan view of an example of a display panel of FIG. 1.

FIG. 5 illustrates an exploded perspective view of a portion of the display panel of FIG. 4.

FIG. 6 illustrates a top plan view of an example of one of pixels of FIG. 5.

FIG. 7 illustrates a cross-section view taken along line I-I′ of the first pixel of FIG. 6.

FIG. 8 illustrates the angle at which light is emitted from a display panel according to embodiments of the present disclosure.

FIG. 9 illustrates a cross-sectional view for explaining the angle at which light is emitted from a first pixel according to an embodiment of FIG. 8.

FIG. 10A illustrates a cross-sectional view for explaining the angle at which light is emitted from a second pixel according to an embodiment of FIG. 8.

FIG. 10B illustrates another cross-sectional view for explaining the angle at which light is emitted from a second pixel according to an embodiment of FIG. 8.

FIG. 10C illustrates another cross-sectional view for explaining the angle at which light is emitted from a second pixel according to an embodiment of FIG. 8.

FIG. 11 illustrates a cross-sectional view for explaining the angle at which light is emitted from a third pixel according to an embodiment of FIG. 8.

FIG. 12 illustrates a cross-sectional view for explaining the angle at which light is emitted from a fourth pixel according to an embodiment of FIG. 8.

FIG. 13 illustrates a cross-sectional view for explaining the angle at which light is emitted from a fifth pixel according to an embodiment of FIG. 8.

FIG. 14A illustrates a top view of a display panel according to embodiments of the present disclosure.

FIG. 14B, 14C, 14D and FIG. 14E illustrate side views of a display panel according to embodiments of the present disclosure.

FIG. 15 illustrates a cross-sectional view for explaining the angle at which light is emitted from a first pixel according to another embodiment of FIG. 8.

FIG. 16A illustrates a cross-sectional view for explaining the angle at which light is emitted from a second pixel according to another embodiment of FIG. 8.

FIG. 16B illustrates another cross-sectional view for explaining the angle at which light is emitted from a second pixel according to another embodiment of FIG. 8.

FIG. 17 illustrates a cross-sectional view for explaining the angle at which light is emitted from a third pixel according to another embodiment of FIG. 8.

FIG. 18 illustrates a cross-sectional view for explaining the angle at which light is emitted from a fourth pixel according to another embodiment of FIG. 8.

FIG. 19 illustrates a cross-sectional view for explaining the angle at which light is emitted from a fifth pixel according to another embodiment of FIG. 8.

FIG. 20A illustrates a top view of a display panel according to embodiments of the present disclosure.

FIGS. 20B and 20C illustrate side views of a display panel according to embodiments of the present disclosure.

FIGS. 21, 22, 23, 24 and 25 are drawings for explaining a manufacturing method of a display panel according to an embodiment of the present disclosure.

FIGS. 26, 27, 28, 29 and 30 are drawings for explaining a manufacturing method of a display panel according to another embodiment of the present disclosure.

FIGS. 31, 32, 33, 34, 35, 36, and 37 are other drawings for explaining a manufacturing method of a display panel according to an embodiment of the present disclosure.

FIGS. 38, 39, and 40 illustrate lens arrays according to embodiments of the present disclosure.

FIG. 41 illustrates an example of a display system according to embodiments of the present disclosure.

FIG. 42 illustrates a perspective view of an application example of the display system of FIG. 41.

FIG. 43 illustrates a head-mounted display device worn on a user.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals. Therefore, the above-mentioned reference numerals may be used in other drawings.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc. may be exaggerated for clarity.

In addition, the expression “equal to or the same as” in the description may mean “substantially equal to or the same as”. That is, it may be the same enough to convince those skilled in the art to be the same. Even other expressions may be expressions from which “substantially” is omitted.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present invention. Singular forms are intended to include plural forms unless the context clearly indicates otherwise.

Terms such as “below”, “the lower side”, “on”, and “the upper side” are used to describe relationships or configurations of elements shown in the drawing. Such terms are understood to provide relative descriptions based on one or more directions shown in the drawing.

Unless otherwise defined, all terms (including technical and scientific terms) used herein have the same meaning as commonly understood by those skilled in the art to which this disclosure belongs. In addition, terms should be interpreted as having meanings consistent with their meaning in the context of the related art or as defined in commonly used dictionaries, unless as explicitly defined here. Further, the terms should not be limited to being interpreted in an ideal or overly formal sense.

It should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations thereof, in advance.

Hereinafter, embodiments of the present disclosure will be described in detail with reference to the accompanying drawings.

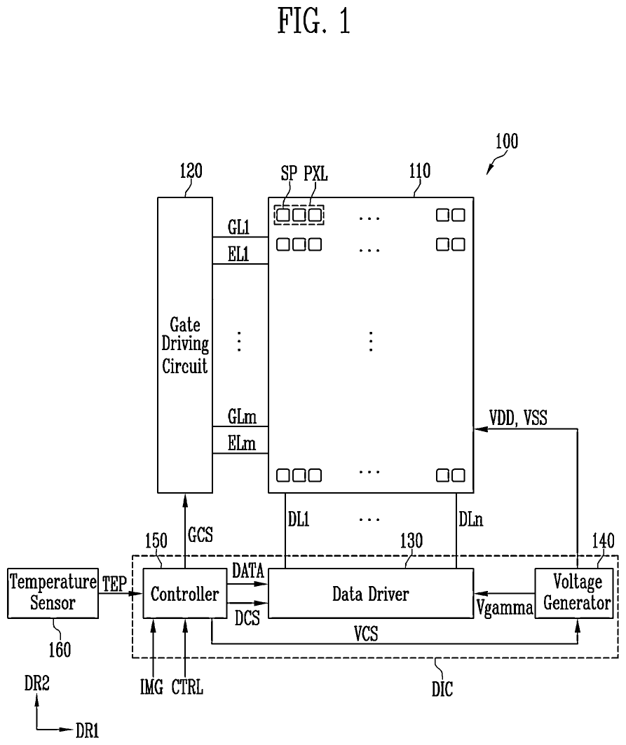

FIG. 1 illustrates a system block diagram of a display device 100 according to an embodiment of the present disclosure.

Referring to FIG. 1, the display device 100 according to the embodiment of the present disclosure may include a display panel 110, a gate driving circuit 120, a data driver 130, a voltage generator 140, a controller 150, and a temperature sensor 160.

The display panel 110 may include a plurality of sub-pixels SP. First to m-th gate lines GL1 to GLm (m is an integer of 2 or more) connected to the plurality of sub-pixels SP may be disposed in the display panel 110. First to n-th data lines DL1 to DLn (n is an integer of 2 or more) connected to the plurality of sub-pixels SP may be disposed in the display panel 110.

The plurality of sub-pixels SP may be connected (for example, electrically connected) to the gate driving circuit 120 through the first to m-th gate lines GL1 to GLm. The plurality of sub-pixels SP may be connected (for example, electrically connected) to the data driver 130 through the first to n-th data lines DL1 to DLn.

Each of the plurality of sub-pixels SP may include at least one light emitting element configured to generate light. Each of the plurality of sub-pixels SP may generate light of a color (for example, a specific color or a specific wavelength band) such as red, green, blue, cyan, magenta, or yellow. Two or more sub-pixels among the plurality of sub-pixels SP may configure one pixel PXL. For example, as shown in FIG. 1, three sub-pixels may constitute one pixel PXL.

The gate driving circuit 120 may be connected (for example, electrically connected) to the plurality of sub-pixels SP (for example, a plurality of sub-pixels SP arranged in a first direction DR1 as a whole) through the first to m-th gate lines GL1 to GLm. For example, the first direction DR1 may be a direction from one side (for example, left side) of the display panel 110 to the other side (for example, right side) thereof. The first direction DR1 may be, for example, a row direction.

The gate driving circuit 120 may output gate signals (for example, a gate signal at a turn-on level or turn-off level) to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, and the like.

In embodiments, first to m-th light emitting control lines EL1 to ELm connected to the plurality of sub-pixels SP may be further disposed in the display panel 110. The first to m-th light emitting control lines EL1 to ELm may be disposed to extend in the row direction in the display panel 110. The plurality of sub-pixels SP may be connected (for example, electrically connected) to the first to m-th light emitting control lines EL1 to ELm. In the above embodiment, the gate driving circuit 120 may include a light emitting control driver configured to control the first to m-th light emitting control lines EL1 to ELm. The light emitting control driver may operate under the control of the controller 150.

The gate driving circuit 120 may be disposed on one side of the display panel 110. However, embodiments are not limited thereto. For example, the gate driving circuit 120 may include two or more physically and/or logically separated driving circuits, and the driving circuits may be disposed on one side and the other side (for example, the other side of the display panel 110 opposite to one side) of the display panel 110. As such, the gate driving circuit 120 may be disposed within the display panel 110 or around the display panel 110 in various forms according to embodiments.

The data driver 130 may be connected (for example, electrically connected) to the plurality of sub-pixels SP (for example, a plurality of sub-pixels SP arranged in a second direction DR2 as a whole) through the first to n-th data lines DL1 to DLn. For example, the second direction DR2 may be a direction from one side (for example, lower side) of the display panel 110 to the other side (for example, upper side) thereof. The second direction DR2 may be, for example, a column direction.

The data driver 130 may receive image data DATA and data control signal DCS from the controller 150. The data driver 130 may operate in response to the data control signal DCS. In embodiments, the data control signal DCS may include a source start pulse, a source shift clock, a source output enable signal, and the like.

The data driver 130 may use voltages (for example, a gamma voltage Vgamma) from the voltage generator 140 to apply data signals having grayscale voltages corresponding to the image data DATA to the first to n-th data lines DL1 to DLn. When a gate signal (for example, a turn-on level gate signal) is applied to each of the first to m-th gate lines GL1 to GLm, the data signals corresponding to the image data DATA may be applied to the data lines DL1 to DLm. Each of the plurality of sub-pixels SP may receive a data signal applied at the corresponding timing in response to a gate signal (for example, a turn-on level gate signal). The plurality of sub-pixels SP may generate light corresponding to an input data signal. Accordingly, an image may be displayed on the display panel 110.

In embodiments, the gate driving circuit 120 and the data driver 130 may each include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to constituent elements of the display device 100. For example, the voltage generator 140 may receive an input voltage from the outside of the display device 100. The voltage generator 140 may adjust (for example, lower) the level of the received voltage and regulate the level-adjusted voltage. The voltage generator 140 may be configured to generate a plurality of voltages.

The voltage generator 140 may generate, for example, a first power voltage VDD, a second power voltage VSS, and a gamma voltage Vgamma. The generated first and second power voltages VDD and VSS may be applied (for example, commonly applied) to the plurality of sub-pixels SP. The first power voltage VDD may have a relatively high voltage level. The second power voltage VSS may have a lower voltage level than the first power voltage VDD. The generated gamma voltage Vgamma may be provided to the data driver 130. In other embodiments, the first power voltage VDD and/or the second power voltage VSS may be provided by an external device (for example, a power management integrated circuit (PMIC)) of the display device 100.

In some embodiments, the voltage generator 140 may generate different voltages. For example, the voltage generator 140 may generate an initialization voltage that is applied (for example, commonly applied) to the plurality of sub-pixels SP. For example, during a sensing operation to sense electrical characteristics of transistors and/or light emitting element(s) of the plurality of sub-pixels SP, a predetermined reference voltage may be applied to the first to n-th data lines DL1 to DLn, and the voltage generator 140 may generate the reference voltage.

The controller 150 may be configured to control overall operations of the display device 100. The controller 150 may receive input image data IMG and a control signal CTRL for controlling the display of the input image data from the outside. The controller 150 may provide the gate control signal GCS, the data control signal DCS, and the voltage control signal VCS in response to the received control signal CTRL.

The controller 150 may convert the input image data IMG to a signal, which is suitable for the display device 100 or the display panel 110, to output the image data DATA. In embodiments, the controller 150 may output the image data DATA by aligning the input image data IMG to be suitable for the sub-pixels SP of a row unit.

Two or more constituent elements of the data driver 130, the voltage generator 140, and the controller 150 may be mounted in one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate constituent elements within one driver integrated circuit DIC. In other embodiments, at least one of the data driver 130, the voltage generator 140, and the controller 150 may be embedded in a driver integrated circuit DIC, and the other may be embedded in an integrated circuit other than the driver integrated circuit DIC.

The temperature sensor 160 is configured to sense a temperature (for example, a surrounding temperature) and generate temperature data TEP representing the sensed temperature. In some embodiments, the temperature sensor 160 may be disposed in the display panel 110. In some embodiments, the temperature sensor 160 may be disposed to be adjacent to the display panel 110 and/or the driver integrated circuit DIC. In some embodiments, the display device 100 may include two or more temperature sensors 160.

The controller 150 may control various operations of the display device 100 in response to temperature data TEP. In embodiments, the controller 150 may adjust the luminance of an image outputted from the display panel 110 in response to the temperature data TEP. For example, the controller 150 may control constituent elements such as the data driver 130 and/or the voltage generator 140 to adjust at least one of the data signals, the first power voltage VDD, and the second power voltage VSS which are inputted to the display panel 110.

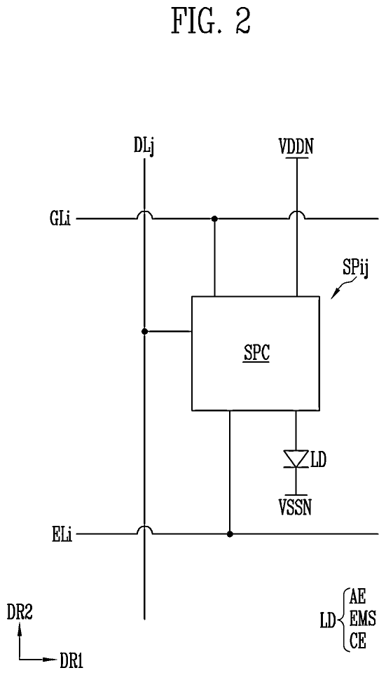

FIG. 2 illustrates a block diagram of an example of one of sub-pixels SPij of FIG. 1.

In FIG. 2, a sub-pixel SPij disposed in an i-th row (i is an integer greater than or equal to 1 and less than or equal to m) and a j-th column (j is an integer greater than or equal to 1 and less than or equal to n) among the plurality of sub-pixels SP shown in FIG. 1 is shown as an example.

Referring to FIG. 2, the sub-pixel SPij may include a sub-pixel circuit SPC and a light emitting element LD.

The light emitting element LD may be connected (for example, electrically connected) between a first power voltage node VDDN and a second power voltage node VSSN. The first power voltage node VDDN may be a node to which the first power voltage VDD of FIG. 1 is applied. The second power voltage node VSSN may be a node to which the second power voltage VSS of FIG. 1 is applied.

The light emitting element LD may include a first electrode, a light emitting structure EMS, and a second electrode. The first electrode may be one of an anode electrode AE and a cathode electrode CE of the light emitting element LD. The second electrode may be the other of the anode electrode AE and the cathode electrode CE of the light emitting element LD. Hereinafter, for better understanding and ease of explanation, it is described as an example that the first electrode of the light emitting element LD is the anode electrode AE, and the second electrode of the light emitting element LD is the cathode electrode CE.

The anode electrode AE of the light emitting element LD may be connected (for example, electrically connected) to the first power voltage node VDDN through the sub-pixel circuit SPC. The cathode electrode CE of the light emitting element LD may be connected (for example, electrically connected) to the second power voltage node VSSN. For example, the anode electrode AE of the light emitting element LD may be connected (for example, electrically connected) to the first power voltage node VDDN through one or more transistors included in the sub-pixel circuit SPC.

The sub-pixel circuit SPC of the sub-pixel SPij may be connected (for example, electrically connected) to an i-th gate line GLi of the first to m-th gate lines GL1 to GLm in FIG. 1. The sub-pixel circuit SPC of the sub-pixel SPij may be connected (for example, electrically connected) to an i-th light emitting control line ELi of the first to m-th light emitting control lines EL1 to ELm in FIG. 1. The sub-pixel circuit SPC of the sub-pixel SPij may be connected (for example, electrically connected) to a j-th data line DLj among the first to n-th data lines DL1 to DLn of FIG. 1. The sub-pixel circuit SPC is configured to control the light emitting timing and/or light emitting luminance of the light emitting element LD according to (or in response to) signals received through these signal lines.

The sub-pixel circuit SPC may operate in response to a gate signal received through the i-th gate line GLi. The sub-pixel circuit SPC may operate in response to a light emitting control signal received through the i-th light emitting control line ELi.

The sub-pixel circuit SPC may receive a data signal through the j-th data line DLj. The sub-pixel circuit SPC may store the voltage of the data signal (or the voltage corresponding to the data signal) in response to a gate signal (for example, a turn-on level gate signal) received through the i-th gate line GLi. The sub-pixel circuit SPC may adjust the timing of current flowing through the light emitting element LD in response to a light emitting control signal (for example, a turn-on level light emitting control signal) applied through the i-th light emitting control line ELi. An amount of the current flowing through the light emitting element LD may vary depending on the voltage stored in the sub-pixel circuit SPC. The light emitting element LD may generate light of luminance corresponding to a data signal.

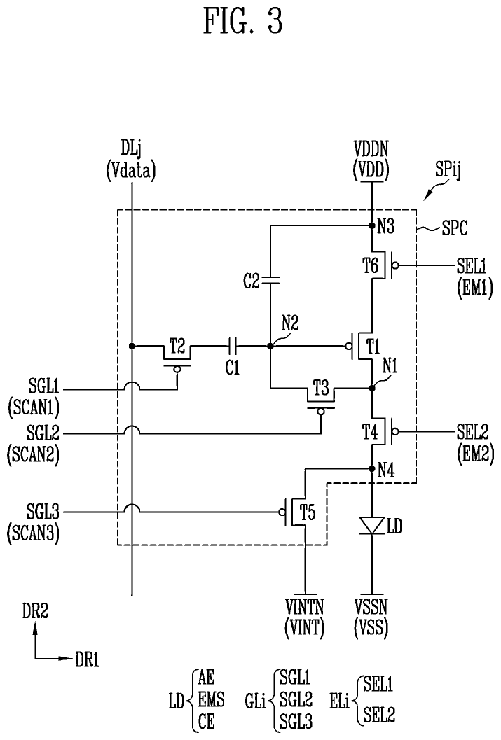

FIG. 3 illustrates an equivalent circuit of an example of the sub-pixel SPij of FIG. 2.

Referring to FIG. 3, the sub-pixel SPij may include a sub-pixel circuit SPC and a light emitting element LD. The sub-pixel circuit SPC may be connected (for example, electrically connected) to the i-th gate line GLi, the i-th light emitting control line ELi, and the j-th data line DLj.

The i-th gate line GLi may include two or more sub-gate lines. Referring to FIG. 3, the i-th gate line GLi may include a first sub-gate line SGL1, a second sub-gate line SGL2, and a third sub-gate line SGL3.

The i-th light emitting control line ELi may include two or more sub-light emitting control lines. Referring to FIG. 3, the i-th light emitting control line ELi may include a first sub-light emitting control line SEL1 and a second sub-light emitting control line SEL2.

The sub-pixel circuit SPC may include two or more switching elements (for example, transistors) and one or more storage elements (for example, capacitors). Referring to FIG. 3, the sub-pixel circuit SPC according to embodiments of the present disclosure may include first to sixth transistors T1 to T6 and first and second capacitors C1 and C2.

The first transistor T1 may be connected between the first power voltage node VDDN and a first node N1. Referring to FIG. 3, the first transistor T1 may be connected between the sixth transistor T6 and the first node N1. A gate of the first transistor T1 may be connected (for example, electrically connected) to a second node N2. The first transistor T1 may be turned on according to the voltage level of the second node N2. An amount of a current (for example, a driving current) flowing through the first transistor T1 may be controlled differently depending on the voltage level of the second node N2. The first transistor T1 may be referred to as a driving transistor.

The second transistor T2 may be connected between the j-th data line DLj and the second node N2. Referring to FIG. 3, the second transistor T2 may be configured to switch the electrical connection between the j-th data line DLj and the first capacitor C1. A gate of the second transistor T2 may be connected to the first sub-gate line SGL1. The second transistor T2 may be controlled in response to a first gate signal SCAN1 applied to the first sub-gate line SGL1. The second transistor T2 may be turned on in response to the first gate signal SCAN1 at the turn-on level. The second transistor T2 may be referred to as a switching transistor.

The third transistor T3 may be configured to switch the electrical connection between the first node N1 and the second node N2. A gate of the third transistor T3 may be connected (for example, electrically connected) to the second sub-gate line SGL2. The third transistor T3 may be controlled in response to a second gate signal SCAN2 applied to the second sub-gate line SGL2. The third transistor T3 may be turned on in response to the second gate signal SCAN2 at the turn-on level.

The fourth transistor T4 may be connected between the first node N1 and the anode electrode AE of the light emitting element LD. Referring to FIG. 3, the fourth transistor T4 may be configured to switch the electrical connection between the first node N1 and a fourth node N4. A gate of the fourth transistor T4 may be connected to the second sub-light emitting control line SEL2. The fourth transistor T4 may be controlled in response to the second light emitting control signal EM2 applied to the second sub-light emitting control line SEL2. The fourth transistor T4 may be turned on in response to the second light emitting control signal EM2 at the turn-on level.

The fifth transistor T5 may be connected between the anode electrode AE of the light emitting element LD and an initialization voltage node VINTN. Referring to FIG. 3, the fifth transistor T5 may be configured to switch the electrical connection between the fourth node N4 and the initialization voltage node VINTN. The initialization voltage node VINTN is configured to transmit an initialization voltage VINT. In embodiments, the initialization voltage VINT may be provided by the voltage generator 140 of FIG. 1. In other embodiments, the initialization voltage VINT may be provided by an external device (for example, a power management integrated circuit (PMIC)) that is separate from the display device 100. A gate of the fifth transistor T5 may be connected (for example, electrically connected) to the third sub-gate line SGL3. The fifth transistor T5 may be controlled in response to a third gate signal SCAN3 applied to the third sub-gate line SGL3. The fifth transistor T5 may be turned on in response to the third gate signal SCAN3 at the turn-on level.

The sixth transistor T6 may be connected between a first power voltage node VDDN and the first transistor T1. Referring to FIG. 3, the sixth transistor T6 may be configured to switch the electrical connection between a third node N3 and the first transistor T1. A gate of the sixth transistor T6 may be connected to the first sub-light emitting control line SEL1. The sixth transistor T6 may be controlled in response to the first light emitting control signal EM1 applied to the first sub-light emitting control line SEL1. The sixth transistor T6 may be turned on in response to the first light emitting control signal EM1 at the turn-on level.

The first capacitor C1 may be connected between the second transistor T2 and the second node N2. The first capacitor C1 may include one electrode connected (for example, electrically connected) to the second transistor T2 and the other electrode connected (for example, electrically connected) to the second node N2. Due to the coupling phenomenon of the first capacitor C1, a data voltage Vdata (or a voltage corresponding to the data voltage Vdata) may be applied to the second node N2.

The second capacitor C2 may be connected between the third node N3 and the second node N2. The second capacitor C2 may include one electrode connected (for example, electrically connected) to the second node N2 and the other electrode connected (for example, electrically connected) to the third node N3. The second capacitor C2 may be configured to maintain the voltage difference between the second node N2 and the third node N3.

The first capacitor C1 and the second capacitor C2 may not be parasitic capacitors. For example, the first capacitor C1 and the second capacitor C2 may be intentionally formed capacitors.

As described above, the sub-pixel circuit SPC may include the first to sixth transistors T1 to T6 and the first and second capacitors C1 and C2. However, the embodiments of the present disclosure are not limited to the above. The sub-pixel circuit SPC may be implemented as one of various circuits including a plurality of transistors and one or more capacitors. For example, the sub-pixel circuit SPC may include two transistors and one capacitor. Depending on the embodiments of the sub-pixel circuit SPC, the number of sub-gate lines SGL included in the i-th gate line GLi may vary. In some embodiments, the number of sub-light emitting control lines SEL included in the i-th light emitting control line ELi may vary.

Referring to FIG. 3, each of the first to sixth transistors T1 to T6 may be a P-type transistor (for example, a transistor including a P-type semiconductor). At least one of the first to sixth transistors T1 to T6 may be a metal oxide semiconductor field effect transistor (MOSFET). However, the embodiments of the present disclosure are not limited thereto. For example, at least one of the first to sixth transistors T1 to T6 may be replaced with an N-type transistor (for example, a transistor including an N-type semiconductor).

In embodiments, the first to sixth transistors T1 to T6 may include an amorphous silicon semiconductor, a polycrystalline silicon semiconductor, an oxide semiconductor, and the like.

The light emitting element LD may include the anode electrode AE, the cathode electrode CE, and the light emitting structure EMS. The light emitting structure EMS may be disposed between the anode electrode AE and the cathode electrode CE. The data voltage Vdata written to the sub-pixel SPij through the data line DLj (for example, the j-th data line DLj) may be the voltage of the second node N2 which is boosted by the first capacitor C1. When the first and second light emitting control signals EM1 and EM2 are enabled to a turn-on level (for example, a low level), the fourth and sixth transistors T4 and T6 may be turned on. The first transistor T1 may be turned on according to the voltage of the second node N2, and a current (for example, a driving current) corresponding to the voltage of the second node N2 may flow through the first transistor T1. Accordingly, a current may flow from the first power voltage node VDDN to the second power voltage node VSSN. The light emitting element LD may emit light with luminance corresponding to the amount of the flowing current (for example, the driving current).

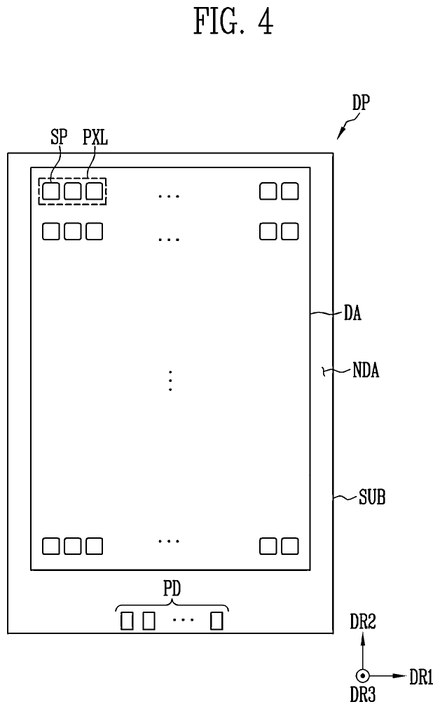

FIG. 4 illustrates a top plan view of an example of a display panel DP of FIG. 1.

The display panel DP of FIG. 4 may be applied to the display panel 110 of FIG. 1.

Referring to FIG. 4, the display panel DP may include a display area DA and a non-display area NDA. The display panel DP may display an image through the display area DA. The non-display area NDA may be disposed around the display area DA (for example, in an edge area thereof).

The display panel DP may include a substrate SUB, a plurality of sub-pixels SP disposed (or formed) on the substrate SUB, and a plurality of pads PD disposed (or formed) on the substrate SUB.

When the display panel DP according to embodiments of the present disclosure is used as a display screen for a head-mounted display (HMD), a virtual reality (VR) device, a mixed reality (MR) device, and an augmented reality (AR) device, the display panel DP may be positioned very close to the user's eyes. In the above embodiment, the sub-pixels SP may be required to be integrated with a relatively high density. In order to increase the degree of integration of the sub-pixels SP, the substrate SUB according to embodiments of the present disclosure may be provided as a silicon substrate. The sub-pixels SP and/or the display panel DP may be formed on the substrate SUB which is a silicon substrate. The display device 100 (see FIG. 1) including the display panel DP formed on the substrate SUB, which is a silicon substrate, may be referred to as an OLED on silicon (OLEDoS) display device.

The plurality of sub-pixels SP may be disposed in the display area DA on the substrate SUB. Referring to FIG. 4, the sub-pixels SP may be arranged in a matrix format along the first direction DR1 and the second direction DR2 that intersects the first direction DR1. However, the embodiments of the present disclosure are not limited thereto. For example, the plurality of sub-pixels SP according to embodiments of the present disclosure may be arranged in a zigzag form along first direction DR1 and second direction DR2. For example, the plurality of sub-pixels SP may be disposed in a PENTILE™ shape. The first direction DR1 may be a row direction, and the second direction DR2 may be a column direction. Among the plurality of sub-pixels SP, two or more sub-pixels SP may configure one pixel PXL.

A constituent element to control the sub-pixels SP may be disposed in the non-display area NDA on the substrate SUB. For example, wires such as the first to m-th gate lines GL1 to GLm and the first to n-th data lines DL1 to DLn in FIG. 1 may extend to at least a portion of the non-display area NDA.

At least one of the gate driving circuit 120, the data driver 130, the voltage generator 140, the controller 150, and the temperature sensor 160 in FIG. 1 may be disposed (for example, integrated and disposed) in the non-display area NDA of the display panel DP.

In the embodiment, the gate driving circuit 120 of FIG. 1 may be formed and disposed in the non-display area NDA of the display panel DP. In another embodiment, the gate driving circuit 120 may be implemented as a separate integrated circuit separate from the display panel DP and be mounted in the non-display area NDA.

In the embodiment, the temperature sensor 160 of FIG. 1 may be disposed in the non-display area NDA to detect the temperature of the display panel DP. For example, the temperature sensor 160 may be disposed at a vertex of the display panel DP or an area corresponding thereto. Two or more temperature sensors 160 may be disposed on the display panel DP.

The pads PD may be disposed in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel DP to other constituent elements of the display device 100 (see FIG. 1). In embodiments, voltages and signals required for operations of constituent elements included in the display panel DP may be provided from the driver integrated circuit DIC of FIG. 1 through the pads PD. For example, the first to n-th data lines DL1 to DLn (see FIG. 1) may be connected to the driver integrated circuit DIC through the pads PD. For example, the first and second power voltages VDD and VSS (see FIG. 1) may be received from the driver integrated circuit DIC through the pads PD. In an embodiment in which the gate driving circuit 120 (see FIG. 1) is mounted on the display panel DP, the gate control signal GCS may be transmitted from the driver integrated circuit DIC to the gate driving circuit 120 through the pads PD.

In embodiments, a circuit board may be electrically connected to the pads PD by using a conductive adhesive member such as an anisotropic conductive film. In this case, the circuit board may be a flexible printed circuit board (FPCB) or a flexible film made of a flexible material. The driver integrated circuit DIC (see FIG. 1) may be mounted on the circuit board to be electrically connected to the pads PD.

In embodiments, the display area DA may have various shapes. For example, the display area DA may have a closed-loop shape including sides of a straight line and/or a curved line. For example, the display area DA may have shapes such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. The display panel DP and/or the substrate SUB may include rigid or flexible materials.

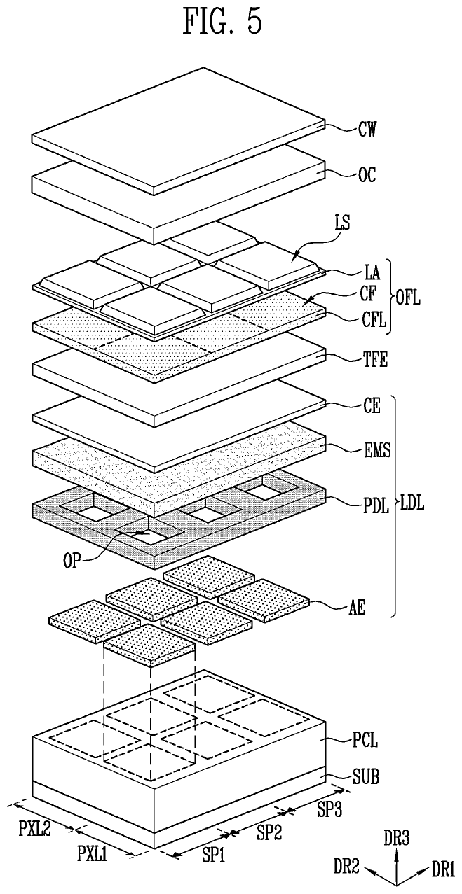

FIG. 5 illustrates an exploded perspective view of a portion of the display panel DP of FIG. 4.

In FIG. 5, for clear and concise description, a portion of the display panel DP corresponding to the first and second pixels PXL1 and PXL2 among the pixels PXL of FIG. 4 is schematically shown. Portions of the display panel DP corresponding to the remaining pixels may be similarly configured to the first and second pixels PXL1 and PXL2.

Referring to FIG. 4 and FIG. 5, the first and second pixels PXL1 and PXL2 may be disposed adjacent to each other in the second direction DR2. Each of the first and second pixels PXL1 and PXL2 may include a plurality of sub-pixels. Referring to FIG. 5, each of the first and second pixels PXL1 and PXL2 may include first, second, and third sub-pixels SP1, SP2, and SP3. However, the embodiments of the present disclosure are not limited thereto. For example, each of the first and second pixels PXL1 and PXL2 may include four sub-pixels, or two sub-pixels.

In FIG. 5, the first to third sub-pixels SP1 to SP3 are shown as having rectangular shapes and the same size when viewed from a third direction DR3 (in a plan view) that intersects the first and second directions DR1 and DR2 (for example, is perpendicular to the first and second directions DR1 and DR2).

However, embodiments are not limited thereto. The first to third sub-pixels SP1 to SP3 may be modified to have various shapes.

The display panel DP may include a substrate SUB, a pixel circuit layer PCL, a light emitting element layer LDL, a thin film encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on Insulator (SOI) layer, or a semiconductor on insulator (SeOI) layer. In other embodiments, the substrate SUB may include a glass substrate. In still other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least some of circuit elements, wires, and the like. The conductive patterns may include copper, but embodiments are not limited thereto.

The circuit elements may include the sub-pixel circuit SPC (see FIG. 2) of each of the first to third sub-pixels SP1 to SP3. The sub-pixel circuit SPC may include two or more transistors and one or more capacitors. Each transistor may include a semiconductor portion including a source area, a drain area, and a channel area, and a gate electrode overlapping the semiconductor portion (for example, the channel area of the semiconductor portion). In an embodiment in which the substrate SUB is provided as a silicon substrate, the semiconductor portion may be a portion of the substrate SUB, and the gate electrode may be included in the pixel circuit layer PCL as the conductive pattern of the pixel circuit layer PCL. In an embodiment in which the substrate SUB is provided as a glass substrate or a PI substrate, the semiconductor portion and the gate electrode may be included in the pixel circuit layer PCL. The capacitor may include electrodes that are spaced apart from each other (for example, that face each other). For example, each capacitor may include electrodes spaced apart from each other along a third direction DR3 extending perpendicular to the first and second directions DR1 and DR2. For example, the capacitor may include electrodes spaced apart from each other in the third direction DR3 with an insulating layer therebetween.

The wires of the pixel circuit layer PCL may include signal lines connected to each of the first to third sub-pixels SP1 to SP3, for example, a gate line, a light emitting control line, and a data line. The wires may further include the wire connected to the first power voltage node VDDN of FIG. 2. The wires may further include the wire connected to the second power voltage node VSSN of FIG. 2.

The light emitting element layer LDL may include anode electrodes AE, a pixel defining film PDL, a light emitting structure EMS, and a cathode electrode CE.

The anode electrodes AE may be disposed on the pixel circuit layer PCL. The anode electrodes AE may be connected to (for example, contact) circuit elements of the pixel circuit layer PCL. The anode electrodes AE may include an opaque conductive material capable of reflecting light. However, the embodiments of the present disclosure are not limited thereto.

The pixel defining film PDL may be disposed on the anode electrodes AE. The pixel defining film PDL may include an opening OP exposing at least a portion of each of the anode electrodes AE. The opening OP of the pixel defining film PDL may correspond to light emitting areas of each of the first to third sub-pixels SP1 to SP3.

In embodiments, the pixel defining film PDL may include an inorganic material. In the above embodiment, the pixel defining film PDL may include an inorganic layer (for example, a plurality of stacked inorganic layers). For example, the pixel defining film PDL may include a silicon oxide (SiOₓ) and/or a silicon nitride (SiNₓ). In other embodiments, the pixel defining film PDL may include an organic layer including an organic material. However, the material configuring the pixel defining film PDL according to the embodiments of the present disclosure is not limited to the above-described material.

The light emitting structure EMS may be disposed on the anode electrodes AE exposed by the opening OP of the pixel defining film PDL. The light emitting structure EMS may include one or more functional layers. For example, the light emitting structure EMS may include functional layers such as a light generating layer (or light emitting layer) (not shown) configured to generate light, an electron transport layer (not shown) configured to transport electrons, and a hole transport layer (not shown) configured to transport holes.

In embodiments, the light emitting structure EMS may fill the opening OP of the pixel defining film PDL. In embodiments, the light emitting structure EMS may be entirely disposed on an upper portion of the pixel defining film PDL. For example, the light emitting structure EMS may extend across the first to third sub-pixels SP1 to SP3. In the above embodiment, at least some of the functional layers in the light emitting structure EMS may be disconnected or bent at the boundaries between the first to third sub-pixels SP1 to SP3. However, the embodiments of the present disclosure are not limited thereto. For example, portions of the light emitting structure EMS corresponding to the first to third sub-pixels SP1 to SP3 are separated from each other, and each of them may be disposed in the opening OP of the pixel defining film PDL.

The cathode electrode CE may be disposed on the light emitting structure EMS. The cathode electrode CE may extend across the first to third sub-pixels SP1 to SP3. The cathode electrode CE may be provided as a common electrode commonly connected to the first to third sub-pixels SP1 to SP3.

The cathode electrode CE may have light transparency. For example, the cathode electrode CE may be a thin metal layer with a thickness sufficient to transmit light emitted from the light emitting structure EMS. The cathode electrode CE may be made of a metal material to have a relatively thin thickness or may be made of a light-transmitting (for example, transparent) conductive material. In embodiments, the cathode electrode CE may include at least one of various transparent conductive materials including an indium tin oxide (ITO), an indium zinc oxide (IZO), an indium tin zinc oxide (ITZO), an aluminum zinc oxide, an indium gallium zinc oxide (IGZO), a zinc tin oxide, and a gallium tin oxide. However, the material configuring the cathode electrode CE according to the embodiments of the present disclosure is not limited to the above-mentioned materials. The cathode electrode CE may function as a half mirror that partially transmits and partially reflects light emitted from the light emitting structure EMS.

One of the anode electrodes AE, the portion of the light emitting structure EMS overlapping it, and the portion of the cathode electrode CE overlapping it may constitute one light emitting element LD (see FIG. 2). Each of the light emitting elements LD of the first to third sub-pixels SP1 to SP3 may include one anode electrode AE, the portion of the light emitting structure EMS overlapping it, and the portion of the cathode electrode CE overlapping it. In each of the first to third sub-pixels SP1 to SP3, holes injected from the anode electrode AE and electrons injected from the cathode electrode CE are transported into the light emitting structure EMS to form excitons, and when the excitons transition from the excited state to the ground state, light may be generated. The luminance of light may be determined depending on the amount of current flowing through the light emitting structure EMS. According to the configuration of the light emitting structure EMS, a wavelength band of light generated by the light emitting structure EMS may be determined.

The thin film encapsulation layer TFE is disposed on the cathode electrode CE. The thin film encapsulation layer TFE may cover the light emitting element layer LDL and/or the pixel circuit layer PCL. The thin film encapsulation layer TFE may be configured to prevent oxygen and/or moisture from penetrating into the light emitting element layer LDL. In embodiments, the thin film encapsulation layer TFE may include a structure in which one or more inorganic films and one or more organic films are alternately stacked. For example, the inorganic film may include a silicon nitride, a silicon oxide, or a silicon oxynitride (SiOₓN_{y}). For example, the organic film may include an organic insulating material such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic film and the inorganic film of the thin film encapsulation layer TFE are not limited to the above-mentioned materials.

The thin film encapsulation layer TFE may further include a thin film containing an aluminum oxide (AlOₓ) in order to improve the encapsulation efficiency of the thin film encapsulation layer TFE. The thin film containing an aluminum oxide may be disposed on the upper surface of the thin film encapsulation layer TFE facing the optical functional layer OFL and/or the lower surface of the thin film encapsulation layer TFE facing the light emitting element layer LDL. The thin film containing the aluminum oxide may be formed through an atomic layer deposition (ALD) method. However, the embodiments of the present disclosure are not limited thereto. The thin film encapsulation layer TFE may further include a thin film made of at least one of various materials suitable for improving the encapsulation efficiency.

The optical functional layer OFL may be disposed on the thin film encapsulation layer TFE. The optical functional layer OFL may include a color filter layer CFL and a lens array LA. In embodiments, the optical functional layer OFL may be attached to the thin film encapsulation layer TFE through an adhesive layer (not shown). For example, the optical functional layer OFL may be separately manufactured and attached to the thin film encapsulation layer TFE through an adhesive layer. The adhesive layer may further perform a function of protecting the lower layers including the thin film encapsulation layer TFE.

The color filter layer CFL may be disposed between the thin film encapsulation layer TFE and the lens array LA. The color filter layer CFL may be configured to selectively output light in a wavelength band corresponding to each sub-pixel by filtering light emitted from the light emitting structure EMS. The color filter layer CFL may include color filters CF corresponding to the first to third sub-pixels SP1 to SP3, respectively. Each of the color filters CF may pass light in the wavelength band corresponding to the corresponding sub-pixel. For example, a color filter CF corresponding to the first sub-pixel SP1 may pass red light, a color filter CF corresponding to the second sub-pixel SP2 may pass green light, and a color filter CF corresponding to the third sub-pixel SP3 may pass blue light. At least some of the color filters CF may be omitted according to light emitted from the light emitting structure EMS in each sub-pixel. In some embodiments, the color filter layer CFL may be omitted. In embodiments, the color filters CF may overlap (for example, partially overlap) in a boundary area between the first to third sub-pixels SP1 to SP3. In other embodiments, the color filters CF are spaced apart from each other in a boundary area between the first to third sub-pixels SP1 to SP3, and a black matrix may be provided between the color filters CF.

The lens array LA may be disposed on the color filter layer CFL. The lens array LA may include lenses LS each of which is disposed in an area corresponding to the first to third sub-pixels SP1 to SP3, respectively. Each of the lenses LS may improve light output efficiency by outputting light emitted from the light emitting structure EMS in an intended path. The lens array LA may have a relatively high refractive index. In embodiments, the lenses LS may include an organic material. In embodiments, the lenses LS may include an acrylate material. However, the material included in the lenses LS is not limited thereto.

In embodiments, at least some of the color filters CF and/or at least some of the lenses LS may be disposed in areas shifted from centers of the openings OP of the pixel defining film PDL. For example, at least some of the color filters CF of the color filter layer CFL and at least some of the lenses LS of the lens array LA may be shifted in one direction parallel to a plane defined by first and second directions DR1 and DR2 from vertical lines passing through centers of the openings OP.

Specifically, in the center area of the display area DA, the center of the color filter CF and the center of the lens LS may be aligned or overlapped with the center of the corresponding opening OP of the pixel defining film PDL when viewed in the third direction DR3. For example, in the central area of the display area DA, the opening OP of the pixel defining film PDL may completely overlap the corresponding color filter CF of the color filter layer CFL and the corresponding lens LS of the lens array LA in a plan view. In an area of the display area DA adjacent to the non-display area NDA, the center of the color filter CF and the center of the lens LS may be shifted in a planar direction from the center of the corresponding opening OP of the pixel defining film PDL when viewed in the third direction DR3. For example, in an area of the display area DA adjacent to the non-display area NDA, the opening OP of the pixel defining film PDL may partially overlap the corresponding color filter CF of the color filter layer CFL and the corresponding lens LS of the lens array LA. Accordingly, at the center of the display area DA, light emitted from the light emitting structure EMS may be efficiently outputted in the normal direction of the display surface. Light emitted from the light emitting structure EMS in areas other than the center of the display area DA may be efficiently outputted in a direction inclined by a predetermined angle with respect to the normal direction of the display surface.

The overcoat layer OC may be disposed on the lens array LA. The overcoat layer OC may cover the optical functional layer OFL, the thin film encapsulation layer TFE, the light emitting structure EMS, and/or the pixel circuit layer PCL. The overcoat layer OC may include various materials suitable for protecting lower layers thereof from foreign substances such as dust and moisture.

The cover window CW may be disposed on the overcoat layer OC. The cover window CW can protect lower layers thereof. In some embodiments, the cover window CW may include light-transmitting (for example, transparent) glass, metal, and the like. However, the embodiments of the present disclosure are not limited thereto.

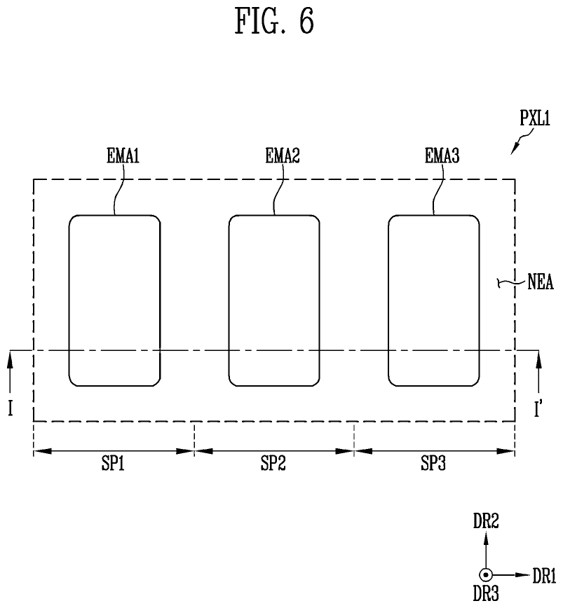

FIG. 6 illustrates a top plan view of an example of one of pixels PXL of FIG. 5.

For a clear and concise description in FIG. 6, the first pixel PXL1 among the first and second pixels PXL1 and PXL2 of FIG. 5 is schematically illustrated. The remaining pixels may be configured similarly to the first pixel PXL1. The first pixel PXL1 may include the first to third sub-pixels SP1 to SP3 arranged in the first direction DR1.

The first sub-pixel SP1 may include a first light emitting area EMA1 and a non-light emitting area NEA surrounding the first light emitting area EMA1. The second sub-pixel SP2 may include a second light emitting area EMA2 and a non-light emitting area NEA surrounding the second light emitting area EMA2. The third sub-pixel SP3 may include a third light emitting area EMA3 and a non-light emitting area NEA surrounding the third light emitting area EMA3.

The first light emitting area EMA1 may be an area in which light is emitted from a portion of the light emitting structure EMS (see FIG. 5) corresponding to the first sub-pixel SP1. The second light emitting area EMA2 may be an area in which light is emitted from a portion of the light emitting structure EMS corresponding to the second sub-pixel SP2. The third light emitting area EMA3 may be an area in which light is emitted from a portion of the light emitting structure EMS corresponding to the third sub-pixel SP3. As described with reference to FIG. 5, each light-emitting area may be understood as the opening OP of the pixel defining film PDL corresponding to each of the first to third sub-pixels SP1 to SP3.

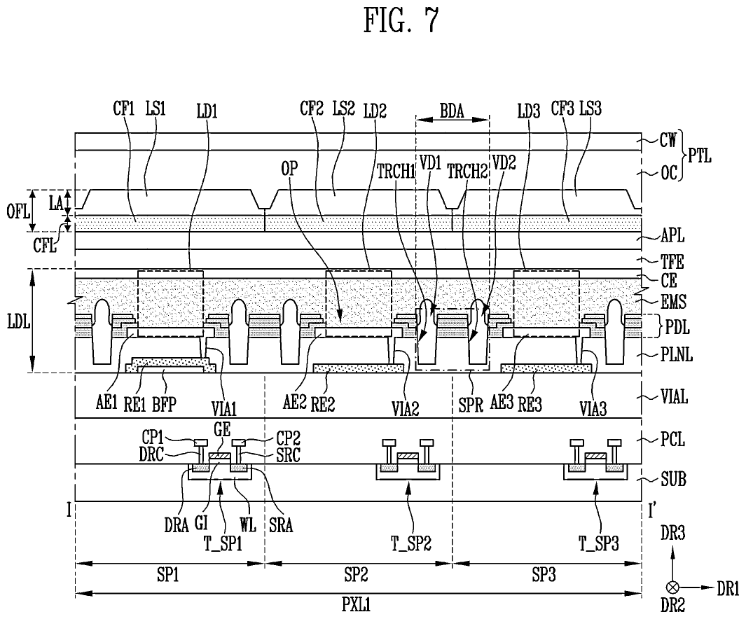

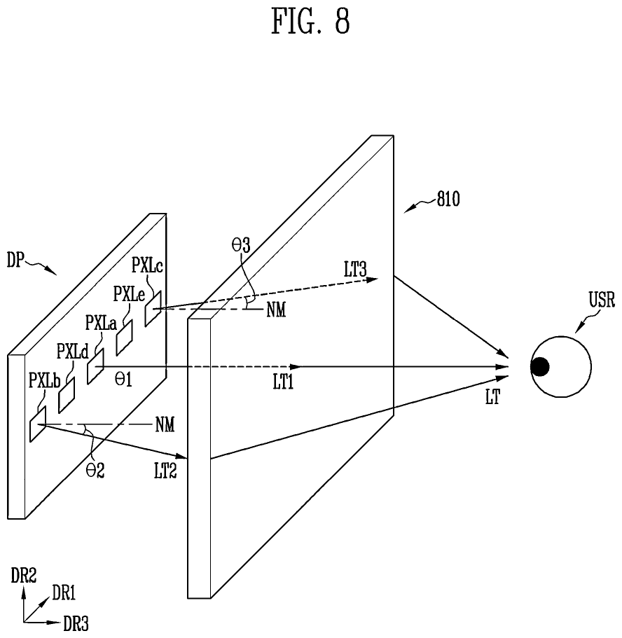

FIG. 7 illustrates a cross-section view taken along line I-I′ of the pixel first PXL1 of FIG. 6.

Referring to FIG. 7, the first pixel PXL1 may include the substrate SUB and the pixel circuit layer PCL disposed on the substrate SUB.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include at least some of circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see FIG. 2) of the first sub-pixel SP1. The transistor T_SP2 of the second sub-pixel SP2 may be one of the transistors included in the sub-pixel circuit SPC of the second sub-pixel SP2. The transistor T_SP3 of the third sub-pixel SP3 may be one of the transistors included in the sub-pixel circuit SPC of the third sub-pixel SP3. In FIG. 7, for clear and concise description, one of the transistors of each of the first to third sub-pixels SP1 to SP3 is illustrated, and the remaining circuit elements of the sub-pixel circuit SPC are not illustrated.

The transistor T_SP1 of the first sub-pixel SP1 may include a source area SRA, a drain area DRA, and a gate electrode GE.

The source area SRA and the drain area DRA may be disposed within the substrate SUB. The source area SRA and the drain area DRA may be disposed to be spaced apart from each other in a well WL formed in the substrate SUB. The well WL may be formed through an ion implantation process. The area between the source area SRA and the drain area DRA within the well WL may be defined as a channel area.

The gate electrode GE may be disposed to overlap (for example, in the third direction DR3) the channel area between the source area SRA and the drain area DRA. The gate electrode GE may be included in the pixel circuit layer PCL. The gate electrode GE may be spaced apart from the well WL (or the channel area) by an insulating material (for example, an insulating material such as a gate insulating layer GI). The gate electrode GE may include a conductive material.

A plurality of layers included in the pixel circuit layer PCL may include insulating layers and conductive patterns disposed between the insulating layers. The conductive patterns of the pixel circuit layer PCL may include first and second conductive patterns CP1 and CP2. The first conductive pattern CP1 may be connected (for example, electrically connected) to the drain area DRA through a drain contact hole DRC formed through one or more insulating layers. The second conductive pattern CP2 may be connected (for example, electrically connected) to the source area SRA through a source contact hole SRC formed through one or more insulating layers.

As the gate electrode GE, the first conductive pattern CP1, and the second conductive pattern CP2 are connected to other circuit elements and/or wires, the transistor T_SP1 of the first sub-pixel SP1 may be provided as one of the transistors of the sub-pixel circuit SPC (see FIG. 2).

Each of the transistor T_SP2 of the second sub-pixel SP2 and the transistor T_SP3 of the third sub-pixel SP3 may be configured similarly to the transistor T_SP1 of the first sub-pixel SP1.

Similar to those described above, the substrate SUB and/or the pixel circuit layer PCL may include circuit elements of each of the first to third sub-pixels SP1 to SP3.

A via layer VIAL may be disposed on the pixel circuit layer PCL. The via layer VIAL may cover the pixel circuit layer PCL. The via layer VIAL may have an overall flat surface (for example, a flat upper surface). The via layer VIAL may planarize steps on the pixel circuit layer PCL. The via layer VIAL may include at least one of inorganic insulating layer such as a silicon oxide (SiOₓ), a silicon nitride (SiNₓ), and a silicon carbon nitride (SiCN), but embodiments of the present disclosure are not limited thereto. The via layer VIAL may include at least one inorganic insulating layer and at least one organic insulating layer.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining film PDL, a light emitting structure EMS, a cathode electrode CE, and the like.

The first to third reflective electrodes RE1 to RE3 may be respectively disposed in the first to third sub-pixels SP1 to SP3 on the via layer VIAL. Each of the first to third reflective electrodes RE1 to RE3 may contact a circuit element disposed in the pixel circuit layer PCL through a via formed through the via layer VIAL.

The first to third reflective electrodes RE1 to RE3 may function as mirrors (for example, full mirrors) that reflect light emitted from the light emitting structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, the embodiments of the present disclosure are not limited thereto.

In embodiments, a buffer electrode (not shown) may be disposed below each of the first to third reflection electrodes RE1 to RE3. The buffer electrode may improve the electrical connection characteristics between the corresponding reflective electrode and the circuit element of the pixel circuit layer PCL. The buffer electrode may have a multi-layered structure. The buffer electrode may include titanium (Ti), a titanium nitride (TiN), a tantalum nitride (TaN), and the like, but embodiments of the present disclosure are not limited thereto. In embodiments, the corresponding reflective electrode may be disposed between the buffer electrodes (for example, between the multilayers configuring the buffer electrode).

At least one of the first to third reflective electrodes RE1 to RE3 may be disposed on a buffer pattern BFP. The buffer pattern BFP may be configured to control the position of the reflective electrode (for example, the position of the reflective electrode in the third direction DR3). The buffer pattern BFP may include an inorganic material such as a silicon carbon nitride, but embodiments of the present disclosure are not limited thereto. Referring to FIG. 7, by disposing the buffer pattern BFP, the position of the corresponding reflective electrode (for example, the height in third direction DR3) may be adjusted. Referring to FIG. 7, the buffer pattern BFP may be disposed between the first reflective electrode RE1 and the via layer VIAL to adjust the height of the first reflective electrode RE1.

The first to third reflective electrodes RE1 to RE3 may function as full mirrors, and the cathode electrode CE may function as a half mirror. At least some of the light emitted from the light emitting structure EMS may be amplified by reciprocating between the corresponding reflective electrode and the cathode electrode CE. The above phenomenon may be understood as a resonance phenomenon. The amplified light may be outputted through the cathode electrode CE. A distance between each reflective electrode and the cathode electrode CE may be understood as a resonance distance for the light emitted from the light emitting structure EMS. The resonance distance may be adjusted by the buffer pattern BFP.

Referring to FIG. 7, the first sub-pixel SP1 may have a shorter resonance distance than other sub-pixels due to the buffer pattern BFP. Light in a specific wavelength band (for example, red color) may be effectively and efficiently amplified by the adjusted resonance distance. Accordingly, the first sub-pixel SP1 may effectively and efficiently output light in the corresponding wavelength band.

Referring to FIG. 7, the buffer pattern BFP is shown to be provided in the first sub-pixel SP1 and not in the second and third sub-pixels SP2 and SP3. However, the embodiments of the present disclosure are not limited thereto. The buffer pattern BFP may be also provided in at least one of the second and third sub-pixels SP2 and SP3, so that the resonance distance of at least one of the second and third sub-pixels SP2 and SP3 may be adjusted. For example, the first to third sub-pixels SP1 to SP3 may correspond to sub-pixels configured to emit light in red, green, and blue colors, respectively. The distance between the first reflective electrode RE1 and the cathode electrode CE may be shorter than the distance between the second reflective electrode RE2 and the cathode electrode CE. The distance between the second reflective electrode RE2 and the cathode electrode CE may be shorter than the distance between the third reflective electrode RE3 and the cathode electrode CE.

The planarization layer PLNL may planarize the steps between the first to third reflective electrodes RE1 to RE3. The planarization layer PLNL may be disposed on the via layer VIAL and the first to third reflective electrodes RE1 to RE3. The planarization layer PLNL may entirely cover the first to third reflective electrodes RE1 to RE3 and the via layer VIAL. The planarization layer PLNL may have a flat surface (for example, an upper surface in the third direction DR3). In some embodiments, the planarization layer PLNL may be omitted.

The first to third anode electrodes AE1 to AE3 may be disposed on the planarization layer PLNL. The first to third anode electrodes AE1 to AE3 may overlap (for example, overlap in the third direction DR3) the first to third reflective electrodes RE1 to RE3, respectively. The first to third anode electrodes AE1 to AE3 may have shapes similar to the first to third light emitting areas EMA1 to EMA3 of FIG. 6 when viewed in the third direction DR3. The first to third anode electrodes AE1 to AE3 are respectively connected to the first to third reflective electrodes RE1 to RE3. The first anode electrode AE1 may be connected (for example, electrically connected) to the first reflective electrode RE1 through the first via VIA1 formed through the planarization layer PLNL. The second anode electrode AE2 may be connected (for example, electrically connected) to the second reflective electrode RE2 through the second via VIA2 formed through the planarization layer PLNL. The third anode electrode AE3 may be connected (for example, electrically connected) to the third reflective electrode RE3 through the third via VIA3 formed through the planarization layer PLNL.

In embodiments, the first to third anode electrodes AE1 to AE3 may include at least one of light-transmitting (for example, transparent) conductive materials such as an indium tin oxide (ITO), an indium zinc oxide (IZO), a zinc oxide (ZnO), an indium gallium zinc oxide (IGZO), and an indium tin zinc oxide (ITZO). However, the materials of the first to third anode electrodes AE1 to AE3 are not limited thereto. For example, the first to third anode electrodes AE1 to AE3 may include a titanium nitride.

The pixel defining film PDL may be disposed on the first to third anode electrodes AE1 to AE3 and the planarization layer PLNL. The pixel defining film PDL may include an opening OP exposing at least a portion of each of the first to third anode electrodes AE1 to AE3. The opening OP of the pixel defining film PDL may define a light emitting area through which light is emitted from each of the first to third sub-pixels SP1 to SP3. The pixel defining film PDL may be disposed in the non-light emitting area NEA in FIG. 6. The pixel defining film PDL may define the first to third light emitting areas EMA1 to EMA3 in FIG. 6.

In embodiments, the pixel defining film PDL may include a plurality of inorganic insulating layers. Each of the plurality of inorganic insulating layers configuring the pixel defining film PDL may include at least one of a silicon oxide (SiOₓ) and a silicon nitride (SiNₓ). For example, the pixel defining film PDL may include first to third inorganic insulating layers sequentially stacked, and each of the first to third inorganic insulating layers may include a silicon nitride, a silicon oxide, and a silicon oxynitride. However, the embodiments of the present disclosure are not limited thereto. The first to third inorganic insulating layers may have a step-shaped cross-section in an area adjacent to the opening OP.

The first pixel PXL1 may include a separator SPR provided (or disposed) in a boundary area BDA between sub-pixels adjacent to each other. In other words, the separator SPR may be provided in each of the boundary areas BDA between the sub-pixels SP in FIG. 4.

The separator SPR may form a discontinuity within the light emitting structure EMS in the boundary area BDA. For example, the light emitting structure EMS may be disconnected or bent in the boundary area BDA by the separator SPR. The separator SPR may be provided in or on the pixel defining film PDL.

The pixel defining film PDL may include one or more trenches TRCH1 and TRCH2 as the separator SPR in the boundary area BDA. In embodiments, as shown in FIG. 7, one or more trenches TRCH1 and TRCH2 may be formed through the pixel defining film PDL, and formed in at least a portion of the planarization layer PLNL. In other embodiments, one or more trenches TRCH1 and TRCH2 may formed through the pixel defining film PDL and the planarization layer PLNL, and may partially formed in at least a portion of the via layer VIAL. In still other embodiments, one or more trenches TRCH1 and TRCH2 may formed through the planarization layer PLNL and/or formed in at least a portion of the via layer VIAL, and at least a portion of the pixel defining film PDL may be disposed in one or more trenches TRCH1 and TRCH2.

Referring to FIG. 7, it is shown that a plurality of trenches (for example, a first trench TRCH1 and a second trench TRCH2) are provided (or disposed) in the boundary area BDA. Hereinafter, for better understanding and ease of description, an embodiment in which two trenches TRCH1 and TRCH2 are provided in the boundary area BDA will be described as an example. However, the embodiments of the present disclosure are not limited thereto. For example, the pixel defining film PDL may include a single (or one) trench in the boundary area BDA. For example, the pixel defining film PDL may include three or more trenches in the boundary area BDA.

Due to the first and second trenches TRCH1 and TRCH2, a void may be formed as a discontinuity in the boundary area BDA. Referring to FIG. 7, discontinuities such as a first void VD1 and a second void VD2 may be formed (or disposed) in the light emitting structure EMS. Some of the plurality of layers stacked in the light emitting structure EMS may be disconnected or bent by the first and second voids VD1 and VD2. For example, at least one charge generation layer CGL included in the light emitting structure EMS may be disconnected in the first and second voids VD1, and VD2. Due to the first and second trenches TRCH1 and TRCH2, at least a portion of the light emitting structure EMS included in the first to third sub-pixels SP1 to SP3 may be partially separated.

Referring to FIG. 7, it is shown that the first and second voids VD1 and VD2 are formed in the light emitting structure EMS in the boundary area BDA. However, this is only an example, and the embodiments of the present disclosure are not limited thereto. For example, a valley of a concave shape may be formed in the light emitting structure EMS in the boundary area BDA. Depending on the shapes of the first and second trenches TRCH1 and TRCH2, the discontinuities formed in the light emitting structure EMS may vary.

In embodiments, the light emitting structure EMS may be formed through a process such as vacuum deposition, inkjet printing, or the like. In the above embodiment, the light emitting structure EMS (or the same materials as the light emitting structure EMS) may fill the first and second trenches TRCH1 and TRCH2 and be disposed on bottom surfaces of the first and second trenches TRCH1 and TRCH2 disposed adjacent to the via layer VIAL in a thickness direction.

The separator SPR may be variously deformed to allow the light emitting structure EMS to be able to have a discontinuity in the boundary area BDA. In embodiments, inorganic insulating patterns stacked on the pixel defining film PDL in the boundary area BDA may be provided instead of the first and second trenches TRCH1 and TRCH2. A width of the uppermost inorganic insulating pattern among the stacked inorganic insulating patterns may be greater than a width of the inorganic insulating pattern disposed directly below the uppermost inorganic insulating pattern. For example, in an embodiment in which the first to third inorganic insulating patterns are sequentially stacked on the pixel defining film PDL in the boundary area BDA, a width of the third inorganic insulating pattern may be greater than a width of the second inorganic insulating pattern disposed directly below the third inorganic insulating pattern. For example, the stacked inorganic insulating patterns may have a cross-section of a “T” or “I” shape in the boundary area BDA. Due to the stacked inorganic insulating patterns having the “T” or “I” shape, at least some of the plurality of layers included in the light emitting structure EMS may be partially disconnected or bent in the boundary area BDA.

The light emitting structure EMS may be disposed on the anode electrodes AE (see FIG. 5) exposed by the opening OP of the pixel defining film PDL. The light emitting structure EMS may fill the opening OP of the pixel defining film PDL, and may be disposed entirely across the first to third sub-pixels SP1 to SP3. As described above, at least a portion of the light emitting structure EMS may be partially disconnected or bent in the boundary area BDA by the separator SPR. Accordingly, during the operation of the display panel DP (see FIG. 4), the current (for example, leakage current) flowing from each of the first to third sub-pixels SP1 to SP3 to the neighboring sub-pixel through the layers included in the light emitting structure EMS may be reduced (or eliminated). Accordingly, the first to third light emitting elements LD1 to LD3 may operate with relatively high reliability.

The cathode electrode CE may be disposed on the light emitting structure EMS. The cathode electrode CE may be commonly provided (or disposed) in the first to third sub-pixels SP1 to SP3. The cathode electrode CE may function as a half mirror that partially transmits and partially reflects light emitted from the light emitting structure EMS.

The first anode electrode AE1, the portion of the light emitting structure EMS overlapping the first anode electrode AE1, and the portion of the cathode electrode CE overlapping the first anode electrode AE1 may constitute the first light emitting element LD1. The second anode electrode AE2, the portion of the light emitting structure EMS overlapping the second anode electrode AE2, and the portion of the cathode electrode CE overlapping the second anode electrode AE2 may constitute the second light emitting element LD2. The third anode electrode AE3, the portion of the light emitting structure EMS overlapping the third anode electrode AE3, and the portion of the cathode electrode CE overlapping the third anode electrode AE3 may constitute the third light emitting element LD3.

The thin film encapsulation layer TFE may be disposed on the cathode electrode CE. The thin film encapsulation layer TFE may prevent oxygen and/or moisture from penetrating into the light emitting element layer LDL.

The optical functional layer OFL may be disposed on the thin film encapsulation layer TFE. The optical functional layer OFL may include the color filter layer CFL and the lens array LA. In embodiments, the optical functional layer OFL may be attached to the thin film encapsulation layer TFE through an adhesive layer APL. For example, the optical functional layer OFL may be separately manufactured and be attached to the thin film encapsulation layer TFE through the adhesive layer APL. The adhesive layer APL may further perform a function of protecting the lower layers including the thin film encapsulation layer TFE.

The color filter layer CFL may include first to third color filters CF1 to CF3 respectively corresponding to the first to third sub-pixels SP1 to SP3. The first to third color filters CF1 to CF3 may pass light in different wavelength bands. For example, the first to third color filters CF1 to CF3 may pass red, green, and blue colored light, respectively.

In embodiments, the first to third color filters CF1 to CF3 may partially overlap in the boundary area BDA. In other embodiments, the first to third color filters CF1 to CF3 may be spaced apart from each other, and a black matrix (not shown) may be provided (or disposed) between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may improve light output efficiency by outputting the light emitted from the first to third light emitting elements LD1 to LD3, respectively, along an intended path.

The overcoat layer OC may be disposed on the lens array LA. The overcoat layer OC may include various materials suitable for protecting lower layers thereof from foreign substances such as dust and moisture. For example, the overcoat layer OC may include an inorganic insulating film. For example, the overcoat layer OC may include an epoxy resin, but embodiments are not limited thereto. The overcoat layer OC may have a lower refractive index than the lens array LA. The refractive index (for example, absolute refractive index) of the overcoat layer OC may be the first refractive index. For example, the range of the first refractive index may be about 1.2 to 1.4, but embodiments of the present disclosure are not limited thereto.

The cover window CW may be disposed on the overcoat layer OC. The cover window CW may have a larger refractive index than the overcoat layer OC. In some embodiments, the cover window CW may include glass, metal, and the like. However, the embodiments of the present disclosure are not limited thereto. The cover window CW may be configured to protect constituent elements disposed therebelow. The refractive index (for example, absolute refractive index) of the cover window CW may be the second refractive index. For example, the range of the second refractive index may be about 1.5 to 1.9, but embodiments of the present disclosure are not limited thereto. The cover window CW may be referred to as an encapsulation glass.

The cover window CW may be in contact with the outside (for example, air). For example, in an embodiment in which the cover window CW is in contact with air, the refractive index (for example, absolute refractive index) of the air may be about 1.0.

The overcoat layer OC and the cover window CW may configure a protective layer PTL. In embodiments of the present disclosure, the protective layer PTL may perform a function of guiding the direction in which light (for example, light emitted from the light emitting element layer LDL) is emitted to the outside of the protective layer PTL.

FIG. 8 illustrates the angle at which light is emitted from the display panel DP according to embodiments of the present disclosure.

Referring to FIG. 8, first to fifth pixels PXLa to PXLe are shown in the display panel DP according to embodiments of the present disclosure.

The first pixel PXLa may represent pixels disposed in a central area of the display panel DP. The second pixel PXLb and the third pixel PXLc may represent pixels disposed in an edge area of the display panel DP. The fourth pixel PXLd and the fifth pixel PXLe may represent pixels disposed between the central area and the edge area of the display panel DP.

Referring to FIG. 8, the first pixel PXLa is shown to be disposed in the first direction DR1 from the second pixel PXLb. However, the embodiments of the present disclosure are not limited thereto. For example, the second pixel PXLb may be disposed in the second direction DR2 from the first pixel PXLa. For example, the second pixel PXLb may be disposed in an area indicated by a vector obtained by adding a vector in the first direction DR1 and a vector in the second direction DR2 from the first pixel PXLa. Hereinafter, for better understanding and ease of description, an embodiment in which the first pixel PXLa is disposed in the first direction DR1 from the second pixel PXLb will be described as an example, but the embodiments of the present disclosure are not limited thereto.

Referring to FIG. 8, the third pixel PXLc is shown to be disposed in the first direction DR1 from the first pixel PXLa. However, the embodiments of the present disclosure are not limited thereto. For example, the third pixel PXLc may be disposed in the second direction DR2 from the first pixel PXLa. For example, the third pixel PXLc may be disposed in an area indicated by a vector obtained by adding a vector in the first direction DR1 and a vector in the second direction DR2 from the first pixel PXLa. Hereinafter, for better understanding and ease of description, an embodiment in which the third pixel PXLc is disposed in the first direction DR1 from the first pixel PXLa will be described as an example, but the embodiments of the present disclosure are not limited thereto.

Referring to FIG. 8, the fourth pixel PXLd is shown to be disposed between the first pixel PXLa and the second pixel PXLb. However, the embodiments of the present disclosure are not limited thereto. For example, the fourth pixel PXLd may not be disposed on a line connecting the first pixel PXLa and the second pixel PXLb. Hereinafter, for better understanding and ease of description, an embodiment in which the fourth pixel PXLd is disposed between the first pixel PXLa and the second pixel PXLb will be described as an example, but the embodiments of the present disclosure are not limited thereto.

Referring to FIG. 8, the fifth pixel PXLe is shown to be disposed between the first pixel PXLa and the third pixel PXLc. However, the embodiments of the present disclosure are not limited thereto. For example, the fifth pixel PXLe may not be disposed on a line connecting the first pixel PXLa and the third pixel PXLc. Hereinafter, for better understanding and ease of description, an embodiment in which the fifth pixel PXLe is disposed between the first pixel PXLa and the third pixel PXLc will be described as an example, but the embodiments of the present disclosure are not limited thereto.

Light LT1 emitted from the first pixel PXLa may be emitted from the display panel DP at an angle (for example, a predetermined angle) with the display panel DP. Referring to FIG. 8, an angle between the light LT1 emitted from the first pixel PXLa and a normal line NM of the display panel DP may be a first angle θ1. The first angle θ1 may be 0°.

Light LT2 emitted from the second pixel PXLb may be emitted from the display panel DP at an angle (for example, a predetermined angle) with the display panel DP. Referring to FIG. 8, an angle between the light LT2 emitted from the second pixel PXLb and the normal line NM of the display panel DP may be a second angle θ2. The second angle θ2 may be an acute angle in a range greater than 0 and less than 90°. For example, the second angle θ2 may be about 40°, but embodiments of the present disclosure are not limited thereto. For example, the second angle θ2 may be about 30°. The light LT2 emitted from the second pixel PXLb may be mainly emitted toward the outside of the display panel DP (or the substrate SUB; see FIG. 5).

Light LT3 emitted from the third pixel PXLc may be emitted from the display panel DP at an angle (for example, a predetermined angle) with the display panel DP. Referring to FIG. 8, an angle between the light LT3 emitted from the third pixel PXLc and the normal line NM of the display panel DP may be a third angle θ3. The third angle θ3 may be an acute angle in a range greater than 0 and less than 90°. For example, the third angle θ3 may be about 40°, but embodiments of the present disclosure are not limited thereto. For example, the third angle θ3 may be about 30°. The light LT3 emitted from the third pixel PXLc may be mainly emitted toward the outside of the display panel DP (or the substrate SUB; see FIG. 5).

An angle between the light emitted from the fourth pixel PXLd and the normal line NM of the display panel DP may be between the first angle θ1 and the second angle θ2. For example, the angle between the light emitted from the fourth pixel PXLd and the normal line NM of the display panel DP may be about 15°. An angle between the light emitted from the fifth pixel PXLe and the normal line NM of the display panel DP may be between the first angle θ1 and the third angle θ3. For example, the angle between the light emitted from the fifth pixel PXLe and the normal line NM of the display panel DP may be about 15°.

The light LT1, LT2, and LT3 emitted from the display panel DP may be incident on an external lens 810. The external lens 810 may refract the incident light LT1, LT2, and LT3. Light LT refracted by the external lens 810 may be emitted in a direction of a user USR. The external lens 810 may be configured to adjust a focal distance. By the external lens 810, the user USR may see the display panel DP disposed close to the user USR more clearly. The external lens 810 may be implemented as, for example, a pancake lens, but embodiments of the present disclosure are not limited thereto.

Depending on a distance between the first pixel PXLa disposed in the center of the display panel DP and any pixel disposed in an arbitrary area of the display panel DP, the angle between the light emitted from a certain pixel and the normal line NM of the display panel DP may vary. For example, the angle between the light emitted from the display panel DP and the normal line NM of the display panel DP may increase from the center area of the display panel DP to the surrounding area (for example, the edge area).

Referring to FIG. 8, the first angle θ1 between the light LT1 emitted from the first pixel PXLa disposed in the central area of the display panel DP and the normal line NM of the display panel DP is 0° which may be the smallest angle. The angle (the second angle θ2 and the third angle θ3) between the light LT2 and LT3 emitted from the second pixel PXLb and the third pixel PXLc disposed in the edge area of the display panel DP and the normal line NM of the display panel DP may be the largest angle.

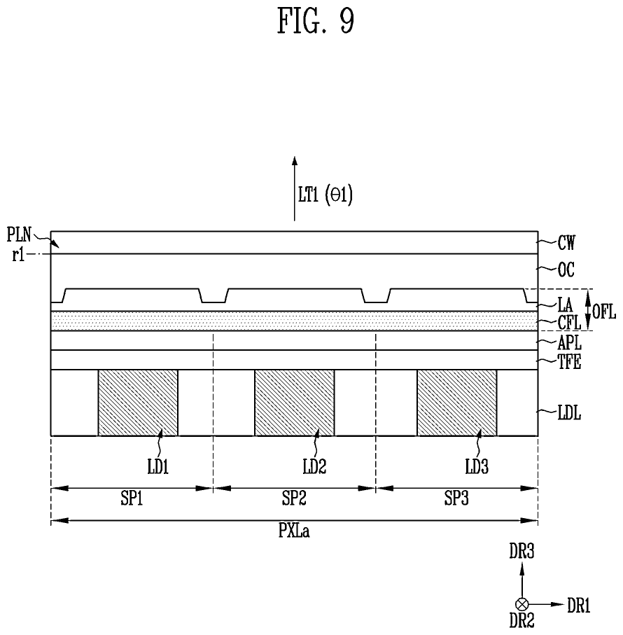

FIG. 9 illustrates a cross-sectional view for explaining the angle at which the light LT1 is emitted from the first pixel PXLa according to the embodiment of FIG. 8.

Referring to FIG. 9, the light LT1 emitted from the first pixel PXLa onto the cover window CW (for example, in the third direction DR3) is shown. The light LT1 may be emitted in a vertical direction, and the first angle θ1 may be 0°.

An inclination angle between the upper surface of the overcoat layer OC and the plane defined by the first direction DR1 and the second direction DR2 may be related to the angle between the light emitted from the pixel and the normal line of the display panel. For example, when the inclination angle between the upper surface of the overcoat layer OC and the plane defined by the first direction DR1 and the second direction DR2 increases, the angle between the normal line of the display panel and the light emitted from the pixel may increase. For example, when the inclination angle between the upper surface of the overcoat layer OC and the plane defined by the first direction DR1 and the second direction DR2 decreases, the angle between the normal line of the display panel and the light emitted from the pixel may decrease.

Referring to FIG. 9, the inclination angle between the upper surface of the overcoat layer OC and the plane defined by the first direction DR1 and the second direction DR2 is shown to be a first inclination angle r1. The first inclination angle r1 may be 0°. The first angle θ1 between the light LT1 emitted from the first pixel PXLa and the normal line of the display panel may be 0°. The upper surface of the overcoat layer OC may include a flat surface PLN.

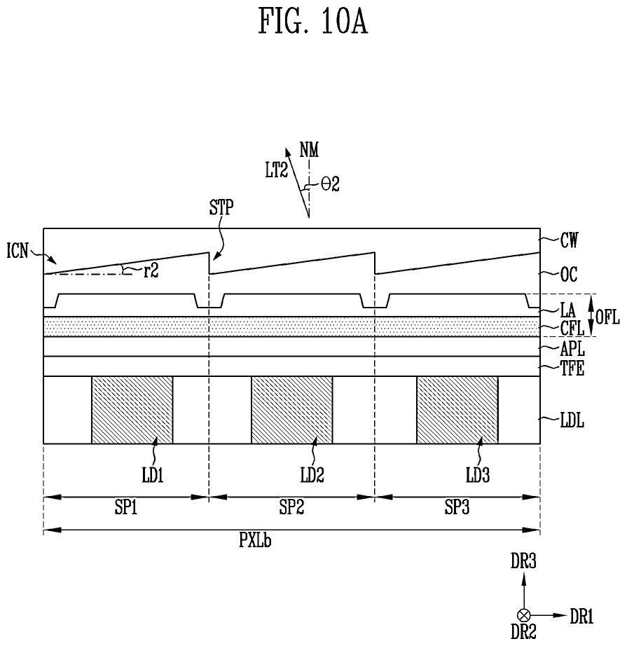

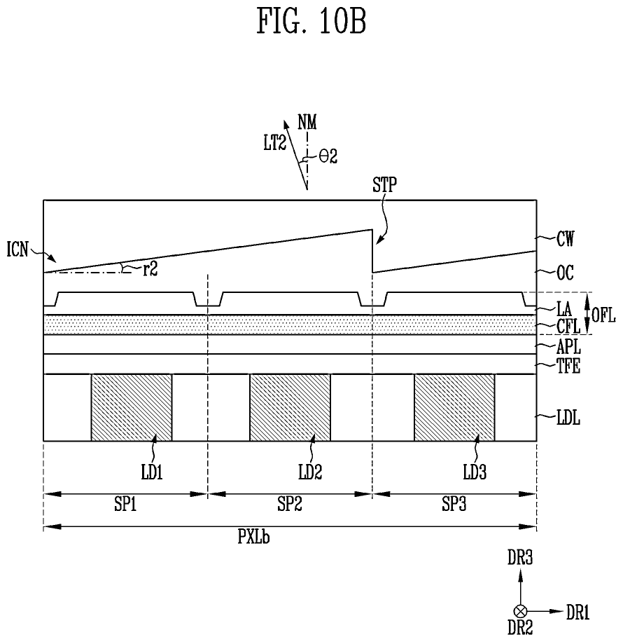

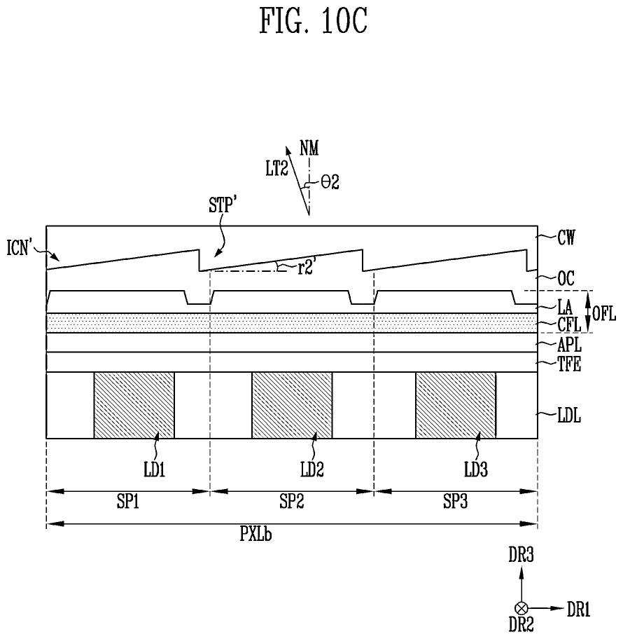

FIG. 10A illustrates a cross-sectional view for explaining the angle at which light LT2 is emitted from the second pixel PXLb according to the embodiment of FIG. 8.

Referring to FIG. 10A, the light LT2 emitted from the second pixel PXLb onto the cover window CW (for example, in the third direction DR3) is shown. The light LT2 may be emitted at the second angle θ2 with the normal line NM.

The inclination angle between the upper surface of the overcoat layer OC and the plane defined by the first direction DR1 and the second direction DR2 is shown to be a second inclination angle r2. The overcoat layer OC may include an inclined surface ICN. An inclination angle of the inclined surface ICN may be the second inclination angle r2. The overcoat layer OC may include a step STP connected to the inclined surface ICN.

The second inclination angle r2 may be an acute angle greater than 0. The second angle θ2 between the light LT2 emitted from the second pixel PXLb and the normal line NM of the display panel may be an acute angle greater than 0.

A refractive index of the overcoat layer OC may be smaller than that of the cover window CW.

In some embodiments, the inclined surface ICN may be disposed in an area corresponding to the sub-pixel SP (see FIG. 4) (for example, units of the light emitting element LD). In some embodiments, one inclined surface ICN may be disposed in an area corresponding to two or more sub-pixels SP (for example, two or more light emitting elements LD). In some embodiments, one inclined surface ICN may be disposed in an area corresponding to one pixel PXL. In some embodiments, one inclined surface ICN may be disposed in an area corresponding to two or more pixels PXL.

Referring to FIG. 10A, an embodiment in which one inclined surface ICN is disposed in an area corresponding to one sub-pixel is shown. In the above embodiment, the inclined surface ICN may be disposed to correspond to the lens array LA and the color filter layer CFL. However, the embodiments of the present disclosure are not limited thereto.

In some embodiments, the step STP may be disposed between adjacent sub-pixels SP (see FIG. 4). In the embodiment, a distance between the step STP and the light emitting element LD of each of the adjacent sub-pixels SP may be same. In another embodiment, distances between the step STP and light emitting elements LD disposed in adjacent sub-pixels SP may be different.

Referring further to FIG. 10A, the inclined surface ICN of the overcoat layer OC may be formed to be inclined such that a height increases from the outside (corresponding to the left side in FIG. 10A) to the inside (corresponding to the right side in FIG. 10A) of the display panel DP.

Referring to FIG. 10A, a refractive index of the overcoat layer OC may be smaller than that of the cover window CW. Accordingly, the light emitted from the light emitting elements LD1, LD2, and LD3 may be refracted on the inclined surface ICN in the direction in which the inclined surface is inclined (primary refraction) and refracted on the upper surface of the cover window CW (secondary refraction). Accordingly, the light emitted from the light emitting elements LD1, LD2, and LD3 may be refracted and emitted in the direction of the outside (corresponding to the left side in FIG. 10A) of the display panel DP (see FIG. 8) with an angle greater than 0 (for example, a predetermined angle) with the normal line NM.

FIG. 10B illustrates another cross-sectional view for explaining the angle at which the light LT2 is emitted from the second pixel PXLb according to the embodiment of FIG. 8.

Referring to FIG. 10B, the light LT2 emitted from the second pixel PXLb onto the cover window CW (for example, in the third direction DR3) is shown. The light LT2 may be emitted at the second angle θ2 with the normal line NM.

One inclined surface ICN may be disposed in an area corresponding to two sub-pixels SP (see FIG. 4). Referring to FIG. 10B, an embodiment in which the inclined surface ICN is disposed in an area corresponding to two sub-pixels (for example, the first sub-pixel SP1 and the second sub-pixel SP2) is shown. In the above embodiment, a number of the inclined surface ICN may be different from that of the lens array LA and the color filter layer CFL. Accordingly, alignment between the overcoat layer OC and light emitting elements LD1, LD2, and LD3 may be easier than the embodiment shown in FIG. 10A.

FIG. 10C illustrates another cross-sectional view for explaining the angle at which the light LT2 is emitted from the second pixel PXLb according to the embodiment of FIG. 8.

Referring to FIG. 10C, the light LT2 emitted from the second pixel PXLb onto the cover window CW (for example, in the third direction DR3) is shown. The light LT2 may be emitted at the second angle θ2 with the normal line NM.

The inclination angle between the upper surface of the overcoat layer OC and the plane defined by the first direction DR1 and the second direction DR2 is shown to be a second inclination angle r2′. The overcoat layer OC may include an inclined surface ICN′. An inclination angle of the inclined surface ICN may be the second inclination angle r2′. The overcoat layer OC may include a step STP connected to the inclined surface ICN′.

The second inclination angle r2′ may be an acute angle greater than 0. The second angle θ2 between the light LT2 emitted from the second pixel PXLb and the normal line NM of the display panel may be an acute angle greater than 0.

The refractive index of the overcoat layer OC may be smaller than the refractive index of the cover window CW.

The optical functional layer OFL may be shifted. For example, at least one of the color filter layer CFL and the lens array LA may be shifted in one direction from the light emitting element LD. Referring to FIG. 10C, in the second pixel PXLb, the color filter layer CFL and the lens array LA may be shifted in a direction opposite to the first direction DR1. The optical functional layer OFL may be shifted toward a direction opposite to the first direction DR1 which is a direction of a horizontal component of the light LT2 emitted from the corresponding pixel (for example, the second pixel PXLb).

In the embodiment in which the optical functional layer OFL is shifted, the size of the step STP′ (or the height of the step STP′) may be relatively smaller than that in the embodiment of FIG. 10A. As a result, the thickness of the overcoat layer OC may be relatively reduced. As a result, it may be possible to provide a thin display panel DP (see FIG. 4).

Distances between the step STP′ and light emitting elements LD disposed in adjacent sub-pixels SP (see FIG. 4) may be different. Referring to FIG. 10C, regarding the step STP′ disposed in the boundary area between the first sub-pixel SP1 and the second sub-pixel SP2, the distance between the step STP′ and the first light emitting element LD1 may be relatively closer than the distance between the step STP′ and the second light emitting element LD2.

Referring to FIG. 10C, the inclined surface ICN′ may be shifted in one direction (for example, the direction opposite to the first direction DR1). Referring further to FIG. 8, the direction in which the inclined surface ICN′ is shifted may be the outer direction (corresponding to the left in FIG. 10C) of the display panel DP. In the above embodiment, the optical functional layer OFL may also be shifted to an outer direction of the display panel DP.

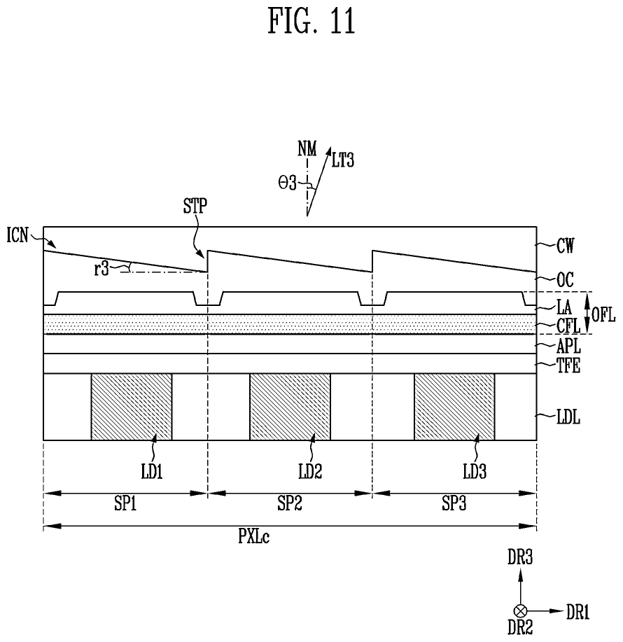

FIG. 11 illustrates a cross-sectional view for explaining the angle at which the light LT3 is emitted from the third pixel PXLc according to the embodiment of FIG. 8.

Referring to FIG. 11, the light LT3 emitted from the third pixel PXLc onto the cover window CW (for example, in the third direction DR3) is shown. The light LT3 may be emitted at the third angle θ3 with the normal line NM.

The inclination angle between the upper surface of the overcoat layer OC and the plane defined by the first direction DR1 and the second direction DR2 is shown to be a third inclination angle r3. The overcoat layer OC may include the inclined surface ICN. The inclination angle of the inclined surface ICN may be the third inclination angle r3. The overcoat layer OC may include the step STP connected to the inclined surface ICN.

The direction in which the inclined surface ICN of the third pixel PXLc is inclined may be opposite to the direction in which the inclined surface ICN of the above-described second pixel PXLb (see FIG. 10A to FIG. 10C) is inclined.

The third inclination angle r3 may be an acute angle greater than 0. The third angle θ3 between the light LT3 emitted from the third pixel PXLc and the normal line NM of the display panel may be an acute angle greater than 0. In the embodiment in which the third inclination angle r3 is the same as the second inclination angle r2 (see FIG. 10A to FIG. 10C), the third angle θ3 may be the same (or substantially the same) as the second angle θ2 (see FIG. 10A to FIG. 10C).

Referring to FIG. 11, a refractive index of the overcoat layer OC may be smaller than that of the cover window CW. Accordingly, the light emitted from the light emitting elements LD1, LD2, and LD3 may be refracted on the inclined surface ICN in the direction in which the inclined surface ICN is inclined (primary refraction) and refracted on the upper surface of the cover window CW (secondary refraction). Accordingly, the light emitted from the light emitting elements LD1, LD2, and LD3 may be refracted and emitted in the direction of the outside (corresponding to the right side in FIG. 11) of the display panel DP (see FIG. 8) with an angle greater than 0 (for example, a predetermined angle) with the normal line NM.

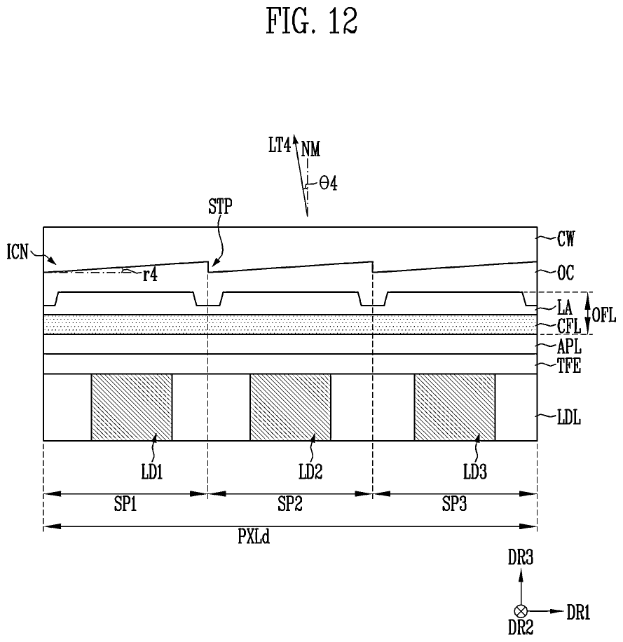

FIG. 12 illustrates a cross-sectional view for explaining the angle at which the light LT4 is emitted from the fourth pixel PXLd according to the embodiment of FIG. 8.

Referring to FIG. 12, the light LT4 emitted from the fourth pixel PXLd onto the cover window CW (for example, in the third direction DR3) is shown. The light LT4 may be emitted at the fourth angle θ4 with the normal line NM.

The inclination angle between the upper surface of the overcoat layer OC and the plane defined by the first direction DR1 and the second direction DR2 is shown to be a fourth inclination angle r4. The overcoat layer OC may include an inclined surface ICN. The inclination angle of the inclined surface ICN may be the fourth inclination angle r4. The overcoat layer OC may include a step STP connected to the inclined surface ICN.

The direction in which the inclined surface ICN of the fourth pixel PXLd is inclined may be the same (or substantially equivalent) as the direction in which the inclined surface ICN of the above-described second pixel PXLb (see FIG. 10A to FIG. 10C) is inclined.

The fourth inclination angle r4 may be an acute angle in a range that is greater than 0 and smaller than the second inclination angles r2 and r2′ (see FIG. 10A to FIG. 10C). The fourth angle θ4 between the light LT4 emitted from the fourth pixel PXLd and the normal line NM of the display panel may be an acute angle greater than 0 and smaller than the second angle θ2 (see FIG. 10A to FIG. 10C).

Referring to FIG. 12, a refractive index of the overcoat layer OC may be smaller than that of the cover window CW. Accordingly, the light emitted from the light emitting elements LD1, LD2, and LD3 may be refracted on the inclined surface ICN in the direction in which the inclined surface ICN is inclined (primary refraction) and refracted on the upper surface of the cover window CW (secondary refraction). Accordingly, the light emitted from the light emitting elements LD1, LD2, and LD3 may be refracted and emitted in the direction of the outside (corresponding to the left side in FIG. 12) of the display panel DP (see FIG. 8) with an angle greater than 0 (for example, a predetermined angle) with the normal line NM.

Referring further to FIGS. 10A and 12, the fourth inclination angle r4 of the fourth pixel PXLd may be smaller than the second inclination angle r2 of the second pixel PXLb. Accordingly, the fourth angle θ4 between the light LT4 emitted from the fourth pixel PXLd and the normal line NM may be smaller than the second angle θ2 between the light LT2 emitted from the second pixel PXLb and the normal line NM.

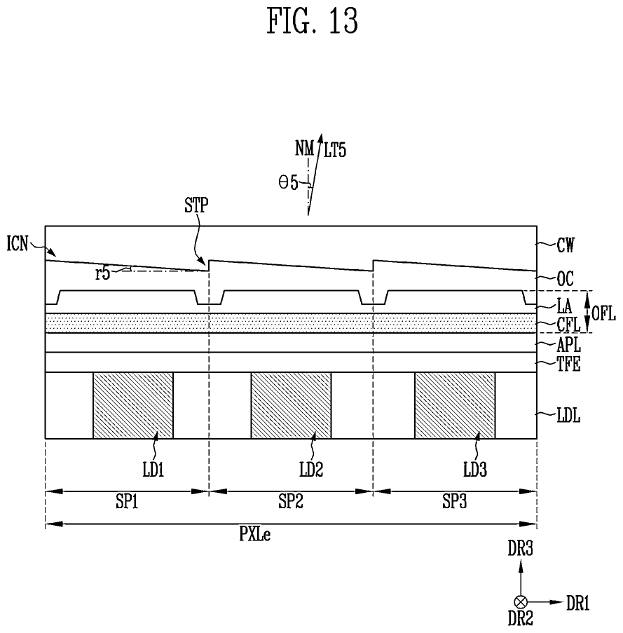

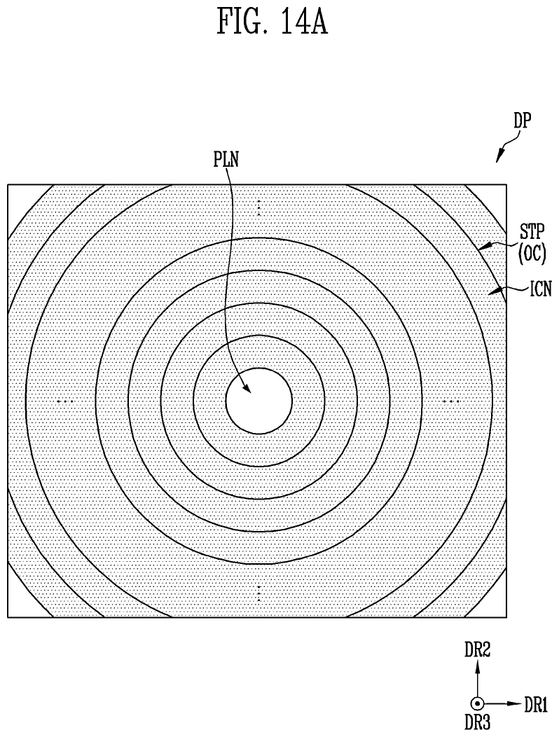

FIG. 13 illustrates a cross-sectional view for explaining the angle at which the light LT5 is emitted from the fifth pixel PXLe according to the embodiment of FIG. 8.

Referring to FIG. 13, the light LT5 emitted from the fifth pixel PXLe onto the cover window CW (for example, in the third direction DR3) is shown. The light LT5 may be emitted at the fifth angle θ5 with the normal line NM.

The inclination angle between the upper surface of the overcoat layer OC and the plane defined by the first direction DR1 and the second direction DR2 is shown to be a fifth inclination angle r5. The overcoat layer OC may include an inclined surface ICN. The inclination angle of the inclined surface ICN may be the fifth inclination angle r5. The overcoat layer OC may include a step STP connected to the inclined surface ICN.

The direction in which the inclined surface ICN of the fifth pixel PXLe is inclined may be opposite to the direction in which the inclined surface ICN of the above-described fourth pixel PXLd (see FIG. 12) is inclined.

The fifth inclination angle r5 may be an acute angle in a range that is greater than 0 and smaller than the third inclination angle r3 (see FIG. 11). The fifth angle θ5 between the light LT5 emitted from the fifth pixel PXLe and the normal line NM of the display panel may be an acute angle greater than 0 and smaller than the third angle θ3 (see FIG. 11). In the embodiment in which the fifth inclination angle r5 is the same as the fourth inclination angle r4 (see FIG. 12), the fifth angle θ5 may be the same (or substantially the same) as the fourth angle θ4 (see FIG. 12).

Referring to FIG. 13, a refractive index of the overcoat layer OC may be smaller than that of the cover window CW. Accordingly, the light emitted from the light emitting elements LD1, LD2, and LD3 may be refracted on the inclined surface ICN in the direction in which the inclined surface ICN is inclined (primary refraction) and refracted on the upper surface of the cover window CW (secondary refraction). Accordingly, the light emitted from the light emitting elements LD1, LD2, and LD3 may be refracted and emitted in the direction of the outside (corresponding to the right side in FIG. 13) of the display panel DP (see FIG. 8) with an angle greater than 0 (for example, a predetermined angle) with the normal line NM.

Referring further to FIGS. 11 and 13, the fifth inclination angle r5 of the fifth pixel PXLe may be smaller than the third inclination angle r3 of the third pixel PXLc. Accordingly, the fifth angle θ5 between the light LT5 emitted from the fifth pixel PXLe and the normal line NM may be smaller than the third angle θ3 between the light LT3 emitted from the third pixel PXLc and the normal line NM.

Referring to FIG. 8 to FIG. 13 as a whole, from the pixels PXL disposed in the center area of the display panel DP to the pixels PXL disposed in the edge area of the display panel DP, regarding the refractive index (or first refractive index) of the overcoat layer OC and the refractive index (or second refractive index) of the cover window CW, the relationship between the inclination angle r of the inclined surface ICN and the angle θ at which light is emitted may be illustratively described through Table 1 and Table 2 below.

TABLE 1

| First Refractive | 1.2 | | | | | | | | | | | | | | |
|---|---|---|---|---|---|---|---|---|---|---|---|---|---|---|---|
| Index | | | | | | | | | | | | | | | |
| Second | 1.5 | | | | | 1.7 | | | | | 1.9 | | | | |
| Refractive Index | | | | | | | | | | | | | | | |
| r(°) | 0 | 10 | 20 | 30 | 40 | 0 | 10 | 20 | 30 | 40 | 0 | 10 | 20 | 30 | 40 |
| θ(°) | 0 | 3 | 6.2 | 9.7 | 13.7 | 0 | 5 | 10.3 | 16 | 22.5 | 0 | 7 | 14.4 | 22.4 | 31.7 |

TABLE 2

| First Refractive | 1.4 | | | | | | | | | | | | | | |
|---|---|---|---|---|---|---|---|---|---|---|---|---|---|---|---|
| Index | | | | | | | | | | | | | | | |
| Second Refractive | 1.5 | | | | | 1.7 | | | | | 1.9 | | | | |
| Index | | | | | | | | | | | | | | | |
| r(°) | 0 | 10 | 20 | 30 | 40 | 0 | 10 | 20 | 30 | 40 | 0 | 10 | 20 | 30 | 40 |
| θ(°) | 0 | 1 | 2.1 | 3.3 | 4.7 | 0 | 3 | 6.2 | 9.7 | 13.8 | 0 | 5 | 10.3 | 16.1 | 22.7 |

In Table 1 and Table 2, the first refractive index may correspond to the refractive index of the overcoat layer OC. The second refractive index may correspond to the refractive index of the cover window CW. r may correspond to the inclination angle of the inclined surface ICN. θ may correspond to the angle between light emitted from the pixel PXL of the display panel having the inclined surface of the corresponding inclination angle r and the normal line NM of the display panel DP (see FIG. 8). In Table 1 and Table 2, a pixel with an inclination angle r of 0° may correspond to the first pixel PXLa in FIG. 8. In Table 1 and Table 2, a pixel with an inclination angle r of 40° may correspond to the second pixel PXLb or third pixel PXLc of FIG. 8. In Table 1 and Table 2, pixels with inclination angles r of 10° to 30° may correspond to the fourth pixel PXLd or fifth pixel PXLe. The values presented in Table 1 and Table 2 above are merely examples for explaining the present disclosure, and the present disclosure is not construed as being limited to the examples described through Table 1 and Table 2.

Accordingly, the embodiments of the present disclosure may refract light from the display panel DP in a predetermined direction and emit the refracted light. Accordingly, light emitted from the center area and edge area of the display panel DP may be uniformly incident on the user. As a result, color deviation and luminance deviation for each area of the display panel DP may be improved.

The heights of the steps STP and STP′ may be determined by the sub-pixels SP (see FIG. 4) and the inclination angle r. For example, for each of the embodiments in which the inclination angle r is 10°, 20°, 30°, 40°, and 45°, in the embodiment in which the distances between the sub-pixels SP are 1 μm, 3 μm, and 5 μm, the sizes of the steps STP and STP′ may be illustratively described through Table 3 below.

TABLE 3

| r(°) | 10 | | | 20 | | | 30 | | | 40 | | | 45 | | |
|---|---|---|---|---|---|---|---|---|---|---|---|---|---|---|---|
| PP (μm) | 1 | 3 | 5 | 1 | 3 | 5 | 1 | 3 | 5 | 1 | 3 | 5 | 1 | 3 | 5 |
| STP (μm) | 0.18 | 0.53 | 0.88 | 0.36 | 1.09 | 1.82 | 0.58 | 1.73 | 2.89 | 0.84 | 2.52 | 4.2 | 1.00 | 3.00 | 5.00 |

In Table 3, r may correspond to the inclination angle of the inclined surface ICN formed on the overcoat layer OC. PP may correspond to the distance between the sub-pixels. STP may correspond to the size of the step (or the height of the step). Referring to Table 3, the step STP formed in the overcoat layer OC in the display panel DP may be 0 to 5 μm.

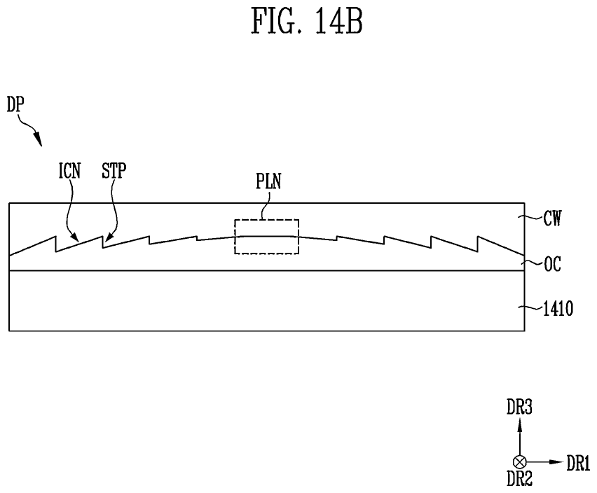

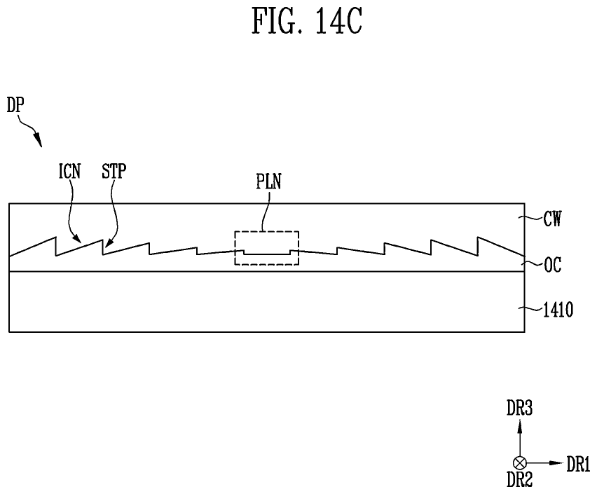

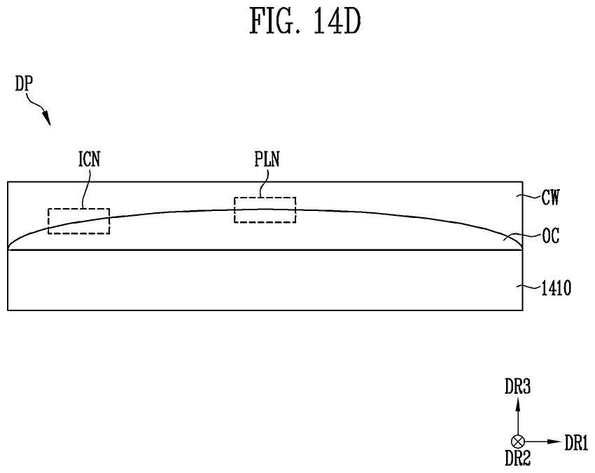

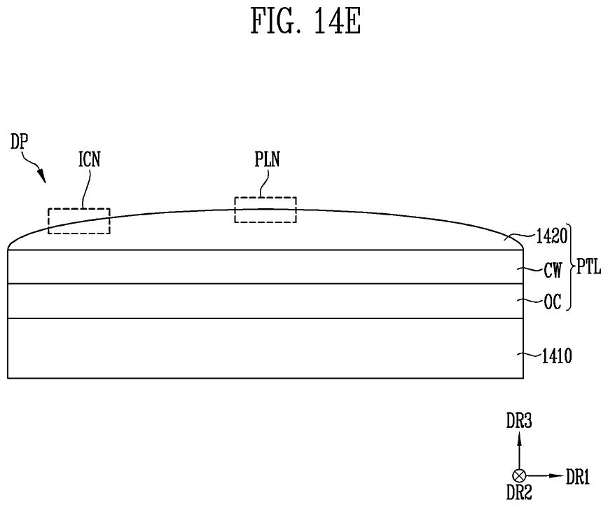

FIG. 14A illustrates a top view of the display panel DP according to embodiments of the present disclosure.

Referring to FIG. 14A, in the display panel DP according to the embodiments of the present disclosure, the flat surface PLN disposed in the central area of the display panel DP, and the inclined surfaces ICN surrounding the flat surface PLN may be disposed.

The inclined surface ICN may be an area between the steps STP. The step STP may be disposed in the form of concentric circles surrounding the flat surface PLN. The step STP may be formed in the overcoat layer OC.

As the distance from the flat surface PLN disposed at the center of the display panel DP increases, the inclination angle of the inclined surface ICN may gradually increase.

FIG. 14B to FIG. 14E illustrate of side views of the display panel DP according to the embodiments of the present disclosure.

Referring to FIG. 14B, the display panel DP according to the embodiments of the present disclosure may include a lower substrate 1410, an overcoat layer OC disposed on the lower substrate 1410, and a cover window CW disposed on the overcoat layer OC. The lower substrate 1410 may include the substrate SUB or the optical functional layer OFL described above in FIG. 5.

As shown in FIG. 14B, in the overcoat layer OC according to the embodiments of the present disclosure, the uppermost ends of the plurality of inclined surfaces ICN and the flat surface PLN may be disposed on the same plane.

As shown in FIG. 14C, in the overcoat layer OC according to the embodiments of the present disclosure, the lowermost ends of the plurality of inclined surfaces ICN and the flat surface PLN may be disposed on the same plane.

As shown in FIG. 14D, the overcoat layer OC according to the embodiments of the present disclosure may not include steps and may be configured of only the inclined surface ICN and the flat surface PLN.

In the embodiment of FIG. 14D, the thickness of the overcoat layer OC in the central area of the lower substrate 1410 may be relatively thick, and the thickness of the overcoat layer OC in the edge area of the lower substrate 1410 may be relatively thin.

According to the embodiment of FIG. 14D, alignment between the overcoat layer OC and light emitting elements LD1, LD2, and LD3 may be easier than the embodiments shown in FIG. 10A to FIG. 10C.

Referring to FIG. 14E, the display panel DP according to the embodiments of the present disclosure may include a lower substrate 1410, an overcoat layer OC, a cover window CW, and a light refractive layer 1420.

Referring to FIG. 14E, the light refractive layer 1420 may include an inclined surface ICN and a flat surface PLN. In some embodiments, the light refractive layer 1420 may further include the above-described steps STP and STP′ (see FIG. 9 to FIG. 13). In the above embodiment, the overcoat layer OC, the cover window CW, and the light refractive layer 1420 may constitute a protective layer PTL. The light refractive layer 1420 may perform a function of guiding a path through which light is emitted from the display panel DP.

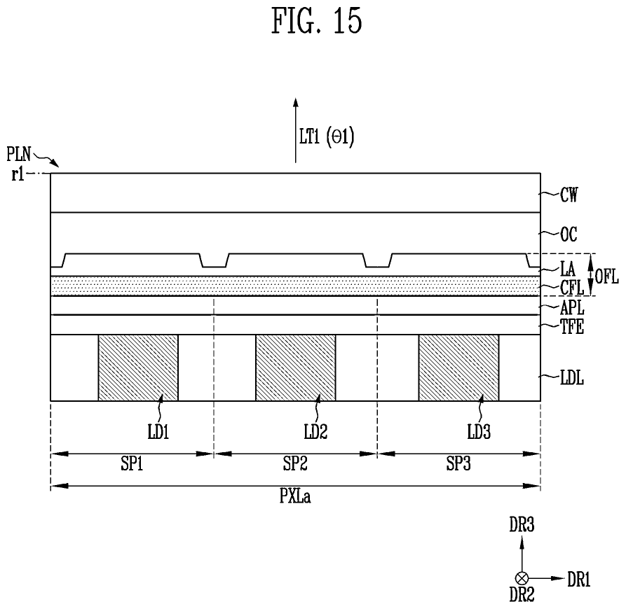

FIG. 15 illustrates a cross-sectional view for explaining the angle at which the light LT1 is emitted from the first pixel PXLa according to another embodiment of FIG. 8.

Referring to FIG. 15, the light LT1 emitted from the first pixel PXLa onto the cover window CW (for example, in the third direction DR3) is shown. The light LT1 may be emitted in a vertical direction, and the first angle θ1 may be 0°.

An inclination angle between the upper surface of the cover window CW and the plane defined by the first direction DR1 and the second direction DR2 may be related to the angle between the light emitted from the pixel and the normal line of the display panel. For example, when the inclination angle between the upper surface of the cover window CW and the plane defined by the first direction DR1 and the second direction DR2 increases, the angle between the normal line of the display panel and the light emitted from the pixel may increase. For example, when the inclination angle between the upper surface of the cover window CW and the plane defined by the first direction DR1 and the second direction DR2 decreases, the angle between the normal line of the display panel and the light emitted from the pixel may decrease.

Referring to FIG. 15, the inclination angle between the upper surface of the cover window CW and the plane defined by the first direction DR1 and the second direction DR2 is shown to be a first inclination angle r1. The first inclination angle r1 may be 0°. The first angle θ1 between the light LT1 emitted from the first pixel PXLa and the normal line of the display panel may be 0°. The upper surface of the cover window CW may include a flat surface PLN.

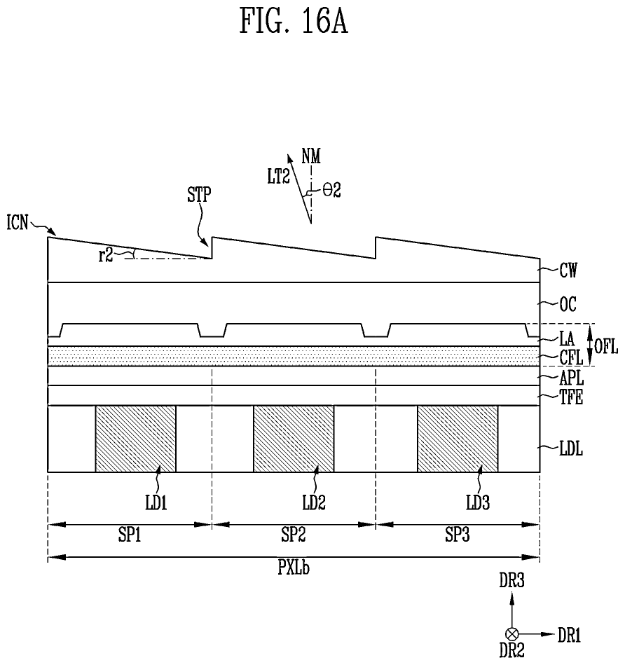

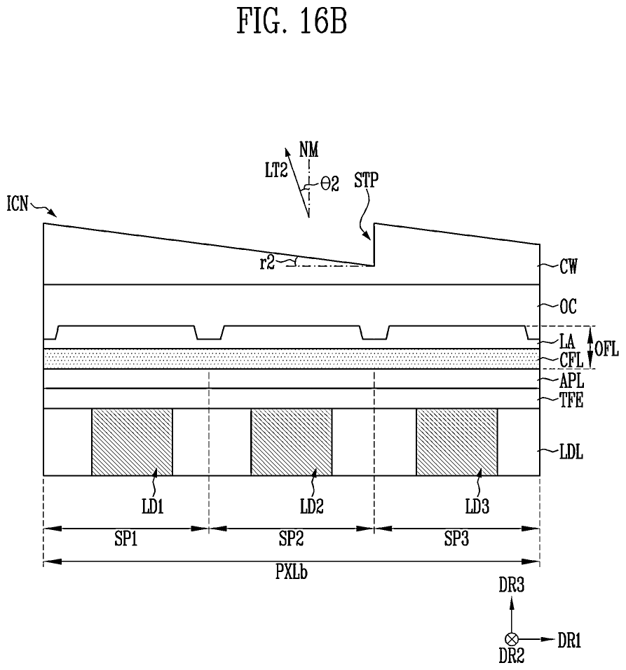

FIG. 16A illustrates a cross-sectional view for explaining the angle at which light is emitted from the second pixel PXLb according to another embodiment of FIG. 8.

Referring to FIG. 16A, the light LT2 emitted from the second pixel PXLb onto the cover window CW (for example, in the third direction DR3) is shown. The light LT2 may be emitted at the second angle θ2 with the normal line NM.

The inclination angle between the upper surface of the cover window CW and the plane defined by the first direction DR1 and the second direction DR2 is shown to be a second inclination angle r2. The cover window CW may include an inclined surface ICN. An inclination angle of the inclined surface ICN may be the second inclination angle r2. The cover window CW may include a step STP connected to the inclined surface ICN.

The second inclination angle r2 may be an acute angle greater than 0. The second angle θ2 between the light LT2 emitted from the second pixel PXLb and the normal line NM of the display panel may be an acute angle greater than 0.

The refractive index of the cover window CW may be larger than the refractive index of the overcoat layer OC. Compared to FIG. 10A, the inclined surface ICN formed in the cover window CW may be formed in an opposite direction compared to the inclined surface ICN (see FIG. 10A) formed in the overcoat layer OC.

In some embodiments, one inclined surface ICN may be disposed in an area corresponding to the sub-pixel SP (see FIG. 4) (or units of the light emitting element LD). In some embodiments, one inclined surface ICN may be disposed in an area corresponding to two or more sub-pixels SP (or two or more light emitting elements LD). In some embodiments, one inclined surface ICN may be disposed in an area corresponding to one pixel PXL. In some embodiments, the inclined surface ICN may be disposed to cover two or more pixels PXL.

Referring to FIG. 16A, an embodiment in which the inclined surface ICN is disposed in an area corresponding to one sub-pixel SP (see FIG. 4) is shown. In the above embodiment, the inclined surface ICN may be disposed to correspond to the lens array LA and the color filter layer CFL. However, the embodiments of the present disclosure are not limited thereto.

In some embodiments, the step STP may be disposed between adjacent sub-pixels SP. In the embodiment, a distance between the step STP and the light emitting element LD of each of the adjacent sub-pixels SP may be same. In another embodiment, distances between the step STP and light emitting elements LD disposed in adjacent sub-pixels SP may be different.

Referring further to FIG. 16A, the inclined surface ICN of the cover window CW may be formed to be inclined such that a height increases from the inside (corresponding to the right side in FIG. 16A) to the outside (corresponding to the left side in FIG. 16A) of the display panel DP (see FIG. 8).

Referring to FIG. 16A, the refractive index of the cover window CW may be greater than the refractive index of the external air. Accordingly, the light emitted from the light emitting elements LD1, LD2, and LD3 may be refracted (primarily refracted) on the inclined surface ICN in a direction opposite to the direction in which the inclined surface is inclined. Accordingly, the light emitted from the light emitting elements LD1, LD2, and LD3 may be refracted and emitted in the direction of the outside (corresponding to the left side in FIG. 16A) of the display panel DP (see FIG. 8) with an angle greater than 0 (for example, a predetermined angle) with the normal line NM.

FIG. 16B illustrates another cross-sectional view for explaining the angle at which the light LT2 is emitted from the second pixel PXLb according to another embodiment of FIG. 8.

Referring to FIG. 16B, the light LT2 emitted from the second pixel PXLb onto the cover window CW (for example, in the third direction DR3) is shown. The light LT2 may be emitted at the second angle θ2 with the normal line NM.

The inclined surface ICN may be disposed in an area corresponding to two sub-pixels SP (see FIG. 4). Referring to FIG. 16B, an embodiment in which the inclined surface ICN is disposed in an area corresponding to two sub-pixels (for example, the first sub-pixel SP1 and the second sub-pixel SP2) of the first to third sub-pixels SP1 to SP3 is shown. In the above embodiment, a number of the inclined surface ICN may be different from that of the lens array LA and the color filter layer CFL. Accordingly, alignment between the cover window CW and light emitting elements LD1, LD2, and LD3 may be easier than the embodiment shown in FIG. 16A.

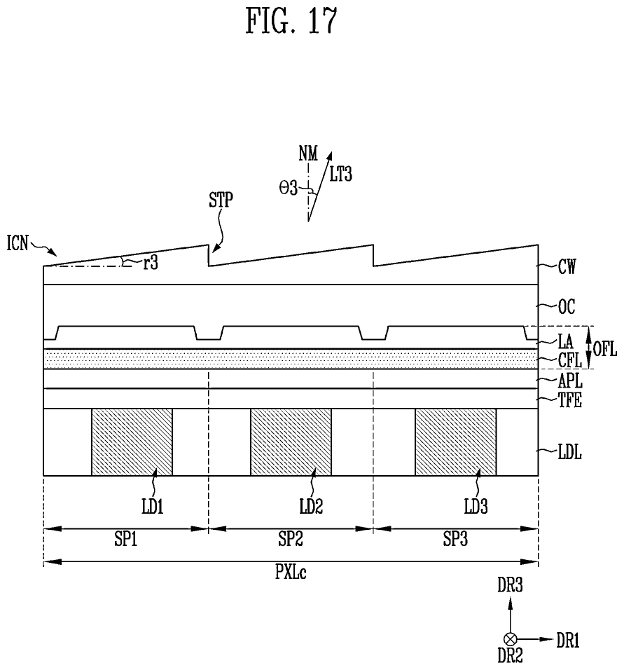

FIG. 17 illustrates a cross-sectional view for explaining the angle at which the light LT3 is emitted from the third pixel PXLc according to another embodiment of FIG. 8.

Referring to FIG. 17, the light LT3 emitted from the third pixel PXLc onto the cover window CW (for example, in the third direction DR3) is shown. The light LT3 may be emitted at the third angle θ3 with the normal line NM.

The inclination angle between the upper surface of the cover window CW and the plane defined by the first direction DR1 and the second direction DR2 is shown to be a third inclination angle r3. The cover window CW may include an inclined surface ICN. The inclination angle of the inclined surface ICN may be the third inclination angle r3. The cover window CW may include a step STP connected to the inclined surface ICN.

The direction in which the inclined surface ICN of the third pixel PXLc is inclined may be opposite to the direction in which the inclined surface ICN of the above-described second pixel PXLb (see FIG. 16A and FIG. 16B) is inclined.

The third inclination angle r3 may be an acute angle greater than 0. The third angle θ3 between the light LT3 emitted from the third pixel PXLc and the normal line NM of the display panel may be an acute angle greater than 0. In the embodiment in which the third inclination angle r3 is the same as the second inclination angle r2 (see FIG. 16A and FIG. 16B), the third angle θ3 may be the same (or substantially the same) as the second angle θ2 (see FIG. 16A and FIG. 16B).

Referring to FIG. 17, the refractive index of the cover window CW may be greater than the refractive index of the external air. Accordingly, the light emitted from the light emitting elements LD1, LD2, and LD3 may be refracted (primarily refracted) on the inclined surface ICN in a direction opposite to the direction in which the inclined surface is inclined. Accordingly, the light emitted from the light emitting elements LD1, LD2, and LD3 may be refracted and emitted in the direction of the outside (corresponding to the right side in FIG. 17) of the display panel DP (see FIG. 8) with an angle greater than 0 (for example, a predetermined angle) with the normal line NM.

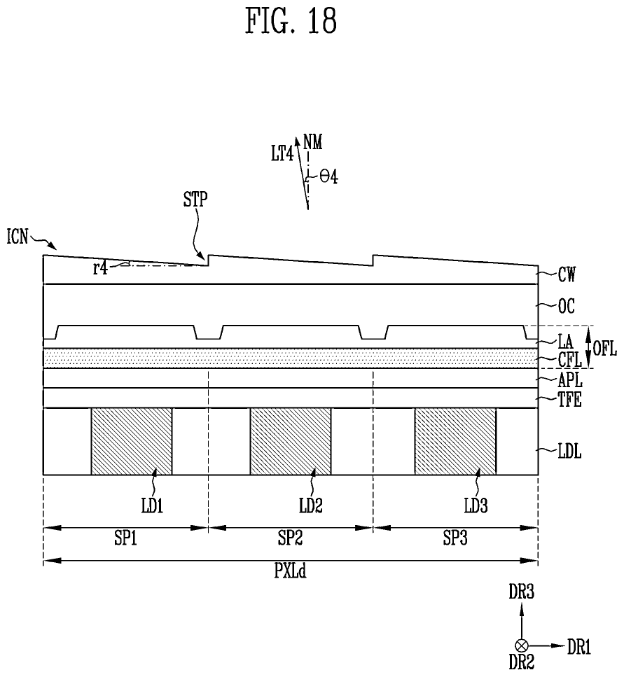

FIG. 18 illustrates a cross-sectional view for explaining the angle at which the light LT4 is emitted from the fourth pixel PXLd according to another embodiment of FIG. 8.

Referring to FIG. 18, the light LT4 emitted from the fourth pixel PXLd onto the cover window CW (for example, in the third direction DR3) is shown. The light LT4 may be emitted at the fourth angle θ4 with the normal line NM.

The inclination angle between the upper surface of the cover window CW and the plane defined by the first direction DR1 and the second direction DR2 is shown to be a fourth inclination angle r4. The cover window CW may include an inclined surface ICN. The inclination angle of the inclined surface ICN may be the fourth inclination angle r4. The cover window CW may include a step STP connected to the inclined surface ICN.

The direction in which the inclined surface ICN of the fourth pixel PXLd is inclined may be the same (or substantially equivalent) as the direction in which the inclined surface ICN of the above-described second pixel PXLb (see FIG. 16A and FIG. 16B) is inclined.

The fourth inclination angle r4 may be an acute angle in a range that is greater than 0 and smaller than the second inclination angle r2 (see FIG. 16A and FIG. 16B). The fourth angle θ4 between the light LT4 emitted from the fourth pixel PXLd and the normal line NM of the display panel may be an acute angle greater than 0 and smaller than the second angle θ2 (see FIG. 16A and FIG. 16B).

Referring to FIG. 18, the refractive index of the cover window CW may be greater than the refractive index of the external air. Accordingly, the light emitted from the light emitting elements LD1, LD2, and LD3 may be refracted (primarily refracted) on the inclined surface ICN in a direction opposite to the direction in which the inclined surface is inclined. Accordingly, the light emitted from the light emitting elements LD1, LD2, and LD3 may be refracted and emitted in the direction of the outside (corresponding to the left side in FIG. 18) of the display panel DP (see FIG. 8) with an angle greater than 0 (for example, a predetermined angle) with the normal line NM.

Referring further to FIGS. 16A and 18, the fourth inclination angle r4 of the fourth pixel PXLd may be smaller than the second inclination angle r2 of the second pixel PXLb. Accordingly, the fourth angle θ4 between the light LT4 emitted from the fourth pixel PXLd and the normal line NM may be smaller than the second angle θ2 between the light LT2 emitted from the second pixel PXLb and the normal line NM.

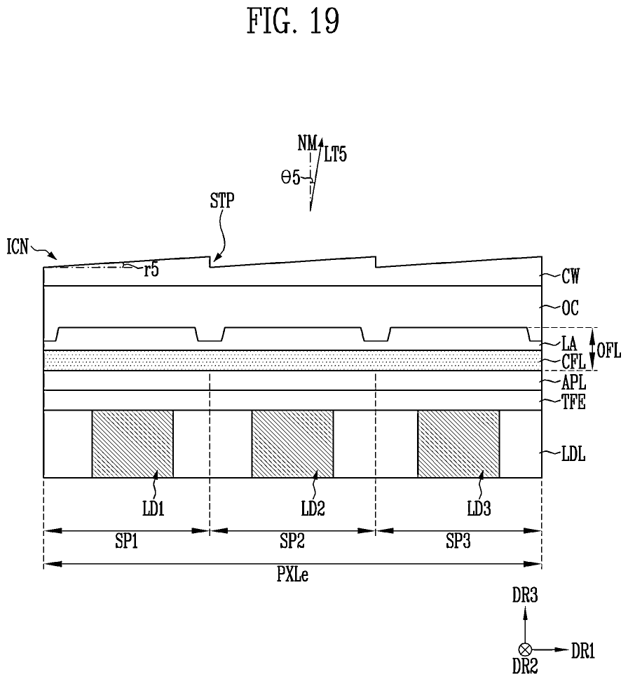

FIG. 19 illustrates a cross-sectional view for explaining the angle at which the light LT5 is emitted from the fifth pixel PXLe according to another embodiment of FIG. 8.

Referring to FIG. 19, the light LT5 emitted from the fifth pixel PXLe onto the cover window CW (for example, in the third direction DR3) is shown. The light LT5 may be emitted at the fifth angle θ5 with the normal line NM.

The inclination angle between the upper surface of the cover window CW and the plane defined by the first direction DR1 and the second direction DR2 is shown to be a fifth inclination angle r5. The cover window CW may include an inclined surface ICN. The inclination angle of the inclined surface ICN may be the fifth inclination angle r5. The cover window CW may include a step STP connected to the inclined surface ICN.

The direction in which the inclined surface ICN of the fifth pixel PXLe is inclined may be opposite to the direction in which the inclined surface ICN of the above-described fourth pixel PXLd (see FIG. 18) is inclined.

The fifth inclination angle r5 may be an acute angle in a range that is greater than 0 and smaller than the third inclination angle r3 (see FIG. 17). The fifth angle θ5 between the light LT5 emitted from the fifth pixel PXLe and the normal line NM of the display panel may be an acute angle greater than 0 and smaller than the third angle θ3 (see FIG. 17). In the embodiment in which the fifth inclination angle r5 is the same as the fourth inclination angle r4 (see FIG. 18), the fifth angle θ5 may be the same (or substantially the same) as the fourth angle θ4 (see FIG. 18).

Referring to FIG. 19, the refractive index of the cover window CW may be greater than the refractive index of the external air. Accordingly, the light emitted from the light emitting elements LD1, LD2, and LD3 may be refracted (primarily refracted) on the inclined surface ICN in a direction opposite to the direction in which the inclined surface is inclined. Accordingly, the light emitted from the light emitting elements LD1, LD2, and LD3 may be refracted and emitted in the direction of the outside (corresponding to the right side in FIG. 19) of the display panel DP (see FIG. 8) with an angle greater than 0 (for example, a predetermined angle) with the normal line NM.

Referring further to FIGS. 17 and 19, the fifth inclination angle r5 of the fifth pixel PXLe may be smaller than the third inclination angle r3 of the third pixel PXLc. Accordingly, the fifth angle θ5 between the light LT5 emitted from the fifth pixel PXLe and the normal line NM may be smaller than the second angle θ2 between the light LT3 emitted from the third pixel PXLc and the normal line NM.

Referring to FIG. 8 and FIG. 15 to FIG. 19 as a whole, from the pixels PXL disposed in the center area of the display panel DP to the pixels PXL disposed in the edge area of the display panel DP, regarding the refractive index (or second refractive index) of the cover window CW, the relationship between the inclination angle r of the inclined surface ICN and the angle θ at which light is emitted may be illustratively described through Table 4 to Table 6 below.

TABLE 4

| Second | | | | | |
|---|---|---|---|---|---|
| Refractive Index | 1.5 | | | | |
| r(°) | 0 | 10 | 20 | 30 | 40 |
| θ(°) | 0 | 5.1 | 10.9 | 18.6 | 34.6 |

TABLE 5

| Second | | | | | |
|---|---|---|---|---|---|
| Refractive Index | 1.55 | | | | |
| r(°) | 0 | 10 | 20 | 30 | 40 |
| θ(°) | 0 | 5.6 | 12 | 20.8 | 45.1 |

TABLE 6

| Second | | | | | |
|---|---|---|---|---|---|
| Refractive Index | 1.6 | | | | |
| r(°) | 0 | 10 | 20 | 30 | 40 |
| θ(°) | 0 | 6.1 | 13.2 | 23.1 | Total |
| | | | | | Refraction |

In Table 4 to Table 6, the second refractive index may correspond to the refractive index of the cover window CW. r may correspond to the inclination angle of the inclined surface ICN. 0 may correspond to the angle between light emitted from the pixel PXL of the display panel having the inclined surface of the corresponding inclination angle r and the normal line NM of the display panel. Referring to Table 6, since light emitted from a light emitting element of a pixel having an inclination angle r of 40° is totally reflected from the inclination surface ICN, the second refractive index may have a value less than 1.6 in the embodiments of FIG. 15 to FIG. 19. Alternatively, in an embodiment in which the second refractive index is 1.6 or more, the inclination angle r of the pixel disposed in the edge area of the display panel DP may have a value less than 40°.

In Table 4 to Table 6, the pixel with an inclination angle r of 0° may correspond to the first pixel PXLa in FIG. 8. In Table 4 to Table 6, the pixel with an inclination angle r of 40° may correspond to the second pixel PXLb or the third pixel PXLc of FIG. 8. In Table 4 to Table 6, pixels with inclination angles r of 10° to 30° may correspond to the fourth pixel PXLd or fifth pixel PXLe, respectively. The values presented in Table 4 to Table 6 above are merely examples for explaining the present disclosure, and the present disclosure is not construed as being limited to the examples described through Table 4 to Table 6.

Accordingly, the embodiments of the present disclosure may refract light from the display panel DP (for example, refract in a predetermined direction) and emit light. Accordingly, light emitted from the center area and edge area of the display panel DP may be uniformly incident on the user. As a result, color deviation and luminance deviation for each area of the display panel DP may be improved.

The size of the step STP (or the height of the step STP) may be determined by the sub-pixels SP (see FIG. 4) and the inclination angle r. For example, for each of the embodiments in which the inclination angle r is 10°, 20°, 30°, 40°, and 45°, in the embodiment in which the distances between the sub-pixels SP are 1 μm, 3 μm, and 5 μm, the sizes of the step STP may be illustratively described through Table 7 below.

TABLE 7

| r(°) | 10 | | | 20 | | | 30 | | | 40 | | | 45 | | |
|---|---|---|---|---|---|---|---|---|---|---|---|---|---|---|---|
| PP (μm) | 1 | 3 | 5 | 1 | 3 | 5 | 1 | 3 | 5 | 1 | 3 | 5 | 1 | 3 | 5 |
| STP (μm) | 0.18 | 0.53 | 0.88 | 0.36 | 1.09 | 1.82 | 0.58 | 1.73 | 2.89 | 0.84 | 2.52 | 4.2 | 1.00 | 3.00 | 5.00 |

In Table 7, r may correspond to the inclination angle of the inclined surface ICN formed on the cover window CW. PP may correspond to the distance between the sub-pixels. STP may correspond to the size of the step (or the height of the step). Referring to Table 7, the step STP formed in the cover window CW in the display panel DP may be 0 to 5 μm.

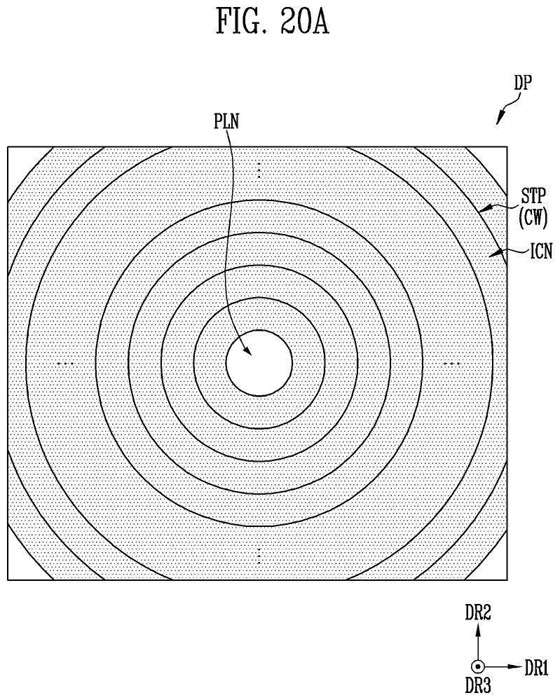

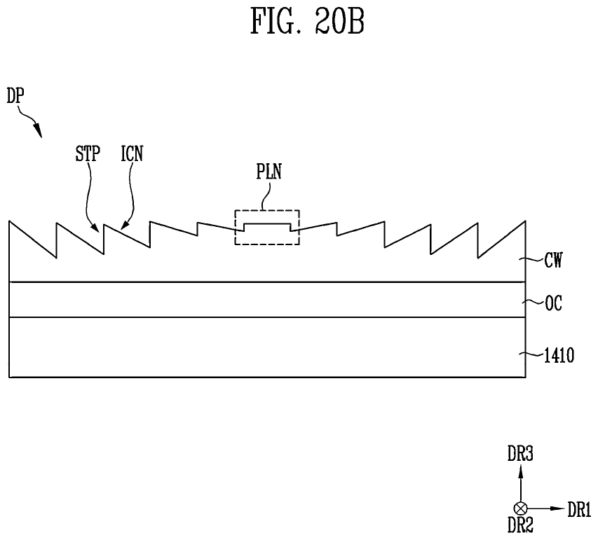

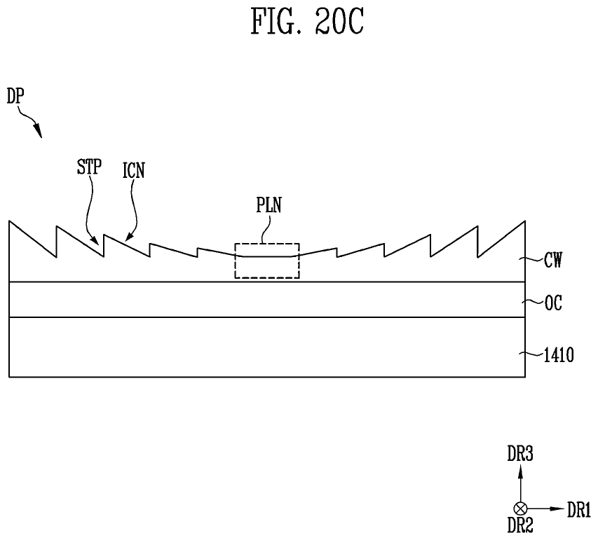

FIG. 20A illustrates a of top view of the display panel DP according to the embodiments of the present disclosure.

Referring to FIG. 20A, in the display panel DP according to the embodiments of the present disclosure, the flat surface PLN disposed in the central area of the display panel DP, and the inclined surfaces ICN surrounding the flat surface PLN may be disposed.

The inclined surface ICN may be an area between the steps STP. The step STP may be disposed in the form of concentric circles surrounding the flat surface PLN. The step STP may be formed in the cover window CW.

As the distance from the flat surface PLN disposed at the center of the display panel DP increases, the inclination angle of the inclined surface ICN may gradually increase.

FIGS. 20B and 20C illustrate side views of the display panel DP according to the embodiments of the present disclosure.

Referring to FIG. 20B, the display panel DP according to the embodiments of the present disclosure may include a lower substrate 1410, an overcoat layer OC on the lower substrate 1410, and a cover window CW on the overcoat layer OC. The lower substrate 1410 may include the substrate SUB or the optical functional layer OFL described above in FIG. 5.

As shown in FIG. 20B, in the cover window CW according to the embodiments of the present disclosure, the uppermost ends of the plurality of inclined surfaces ICN and the flat surface PLN may be disposed on the same plane.

As shown in FIG. 20C, in the cover window CW according to the embodiments of the present disclosure, the lowermost ends of the plurality of inclined surfaces ICN and the flat surface PLN may be disposed on the same plane.

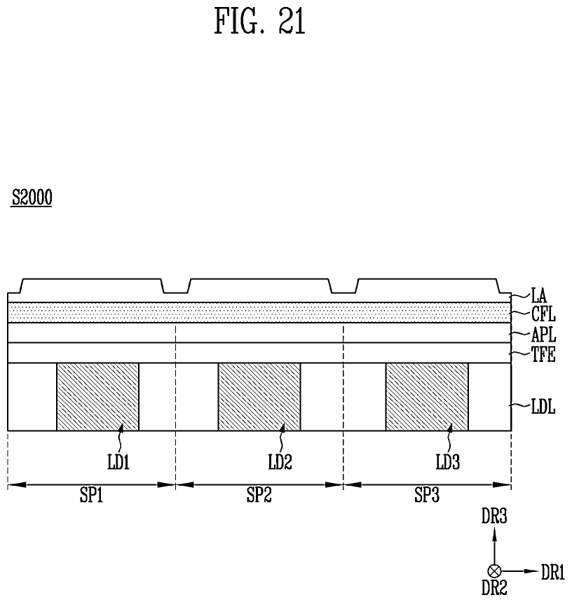

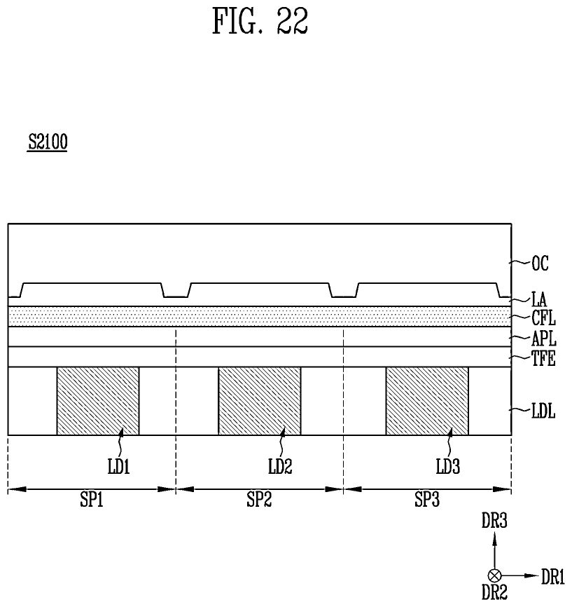

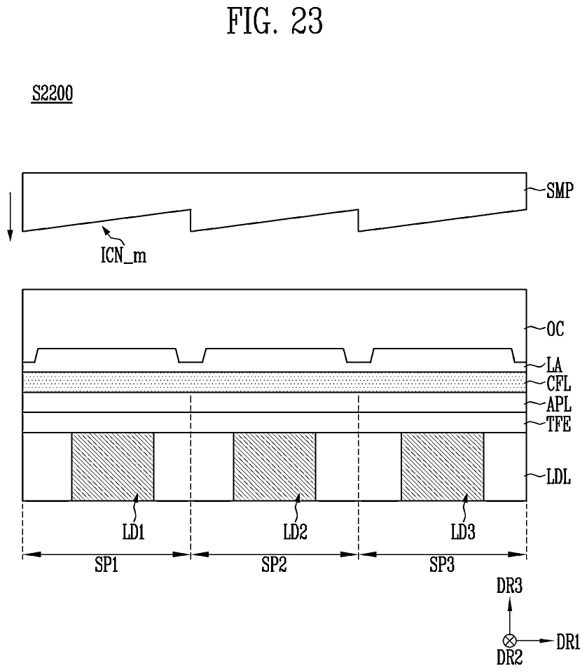

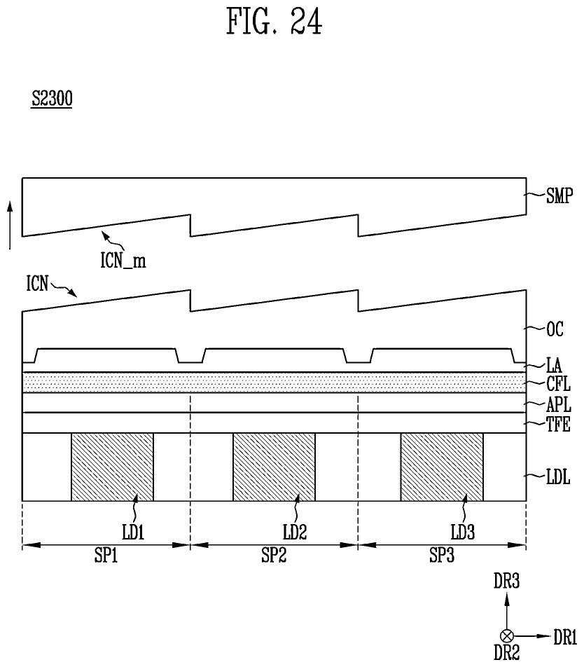

FIGS. 21 to 25 are drawings for explaining a manufacturing method of a display panel according to an embodiment of the present disclosure.

Referring to FIGS. 21 to 25, the manufacturing method of the display panel according to the embodiments of the present disclosure includes preparing a lower substrate (S2000), forming an overcoat layer OC (S2100), pressing with a stamp (S2200), detaching the stamp (S2300), and forming a cover window (S2400).

In the preparing of the lower substrate (S2000), the pixel circuit layer PCL (see FIG. 5), the light emitting element layer LDL, the thin film encapsulation layer TFE, the adhesive layer APL, the color filter layer CFL, and the lens array LA may be sequentially formed on the substrate SUB (see FIG. 5). The lower substrate may be the same as or similar to the lower substrate 1410 described in FIGS. 14B to 14E, FIGS. 20B and 20C.

In the forming of the overcoat layer OC (S2100), the overcoat layer OC may be formed on the lower substrate. For example, in an embodiment in which the overcoat layer OC includes an epoxy resin, the epoxy resin may be applied on the lens array LA in the forming of the overcoat layer OC (S2100).

In the pressing with the stamp (S2200), a stamp SMP may be prepared. The stamp SMP may include an inclined surface mold ICN_m. In the pressing with the stamp (S2200), the stamp SMP may press the protective layer (for example, the overcoat layer OC) in one direction (for example, the direction opposite to the third direction DR3). The protective layer (for example, the overcoat layer OC) may be hardened in the pressing with the stamp (S2200).

In some embodiments, one inclined surface mold ICN_m may be disposed in an area corresponding to one sub-pixel. In some embodiments, one inclined surface mold ICN_m may be disposed in an area corresponding to two or more sub-pixels SP (see FIG. 4). In some embodiments, one inclined surface mold ICN_m may be disposed in an area corresponding to one pixel PXL (see FIG. 4). In some embodiments, the inclined surface mold ICN_m may be disposed in an area corresponding to two or more pixels PXL.

In the removing the stamp (S2300), the stamp SMP may be detached from the protective layer (for example, the overcoat layer OC). The inclined surface ICN corresponding to the inclined surface mold ICN_m may be formed on the protective layer (for example, the overcoat layer OC).

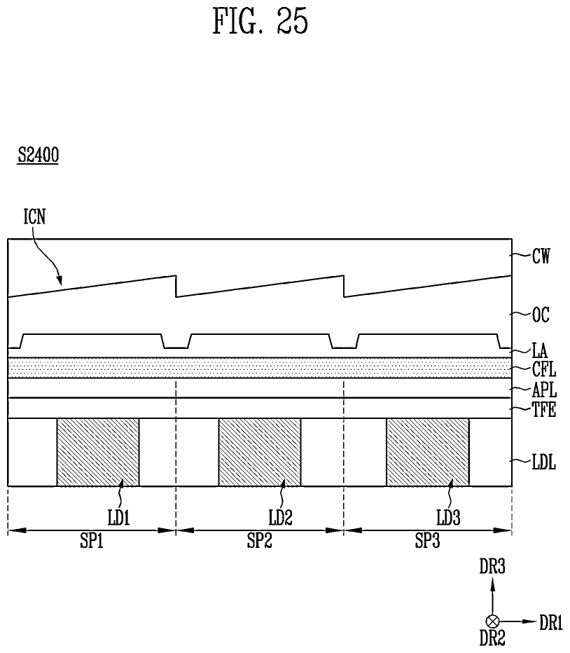

In the forming of the cover window (S2400), the cover window CW may be formed on the overcoat layer OC. Referring to FIG. 25, in the forming of the cover window (S2400), the cover window CW may be formed on the overcoat layer OC on which the inclined surface ICN is formed. For example, in an embodiment in which the cover window CW includes glass, the cover window CW may be formed on the overcoat layer OC in such a way that glass including the inclined surface ICN on the lower surface is disposed on the overcoat layer OC.

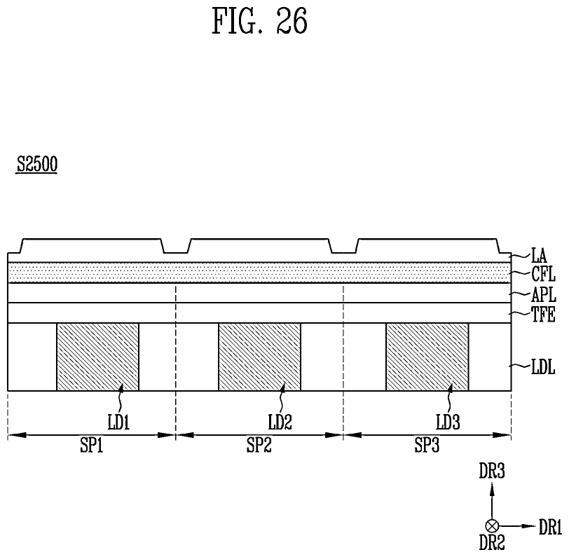

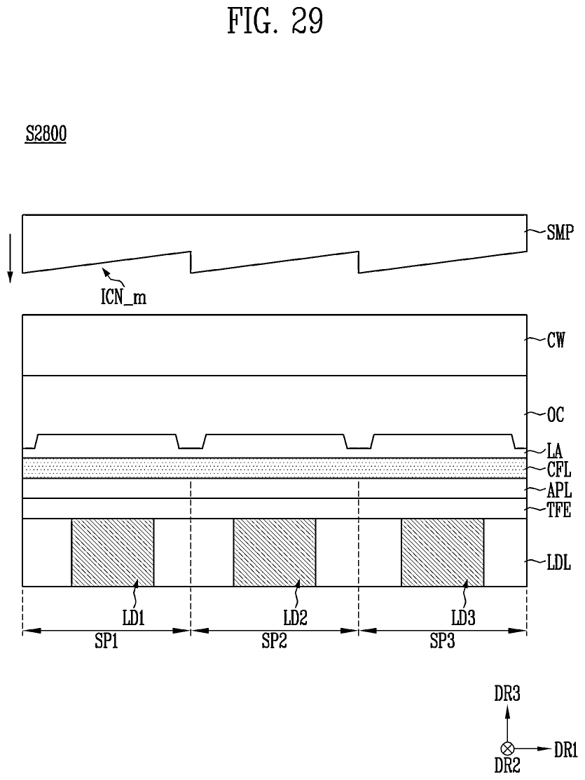

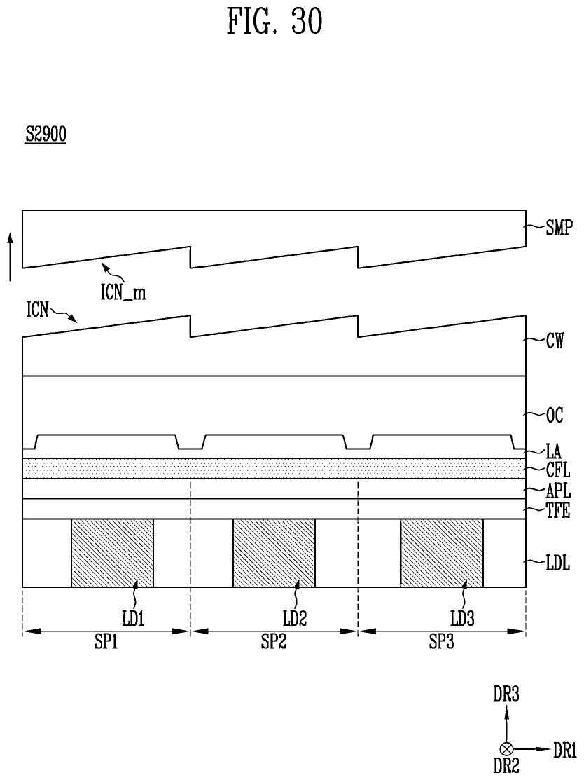

FIGS. 26 to 30 are drawings for explaining a manufacturing method of a display panel according to another embodiment of the present disclosure.

Referring to FIGS. 26 to 30, the manufacturing method of the display panel according to the embodiments of the present disclosure includes preparing a lower substrate (S2500), forming an overcoat layer OC (S2600), forming a cover window (S2700), pressing with a stamp (S2800), and detaching the stamp (S2900).

In the preparing of the lower substrate (S2500), the light emitting element layer LDL, the thin film encapsulation layer TFE, the adhesive layer APL, the color filter layer CFL, and the lens array LA may be sequentially formed on the substrate. The lower substrate may be configured to be the same as or similar to the lower substrate 1410 described in FIGS. 14B to 14E, FIGS. 20B and 20C.

In the forming of the overcoat layer OC (S2600), the overcoat layer OC may be formed on the lower substrate. For example, in an embodiment in which the overcoat layer OC includes an epoxy resin, the epoxy resin may be applied on the lens array LA in the forming of the overcoat layer OC (S2600).

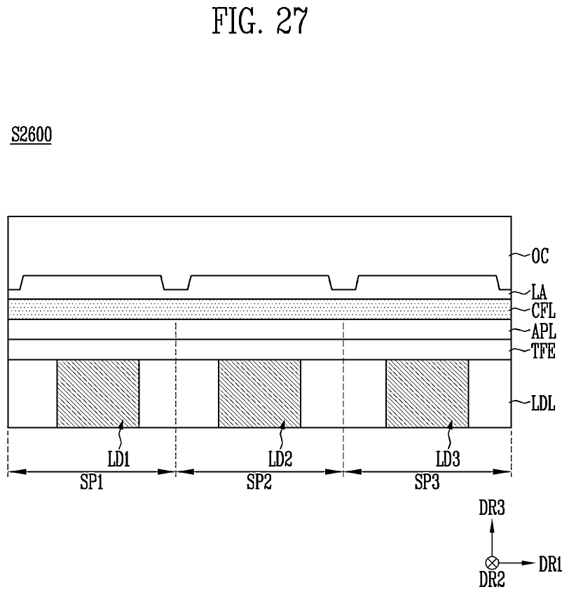

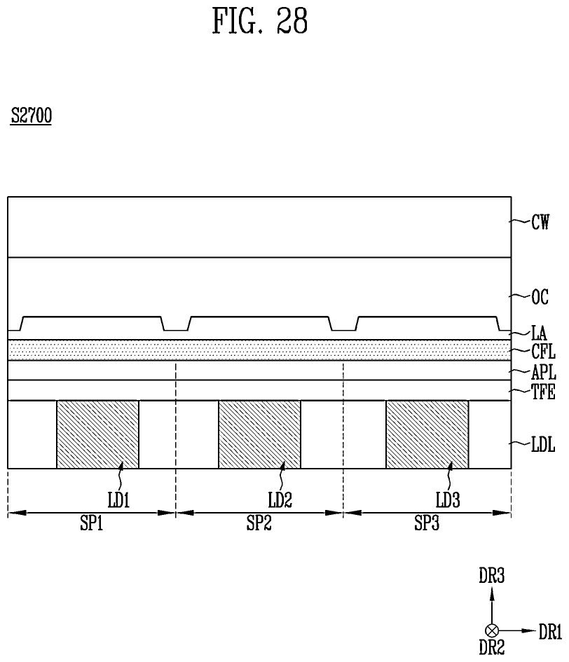

In the forming of the cover window (S2700), the cover window CW may be formed on the overcoat layer OC. Referring to FIG. 28, in the forming of the cover window (S2700), the cover window CW may be formed on the overcoat layer OC with a flat upper surface (for example, a flat surface in the third direction DR3).

In the pressing with the stamp (S2800), a stamp SMP may be prepared. The stamp SMP may include an inclined surface mold ICN_m. In the pressing with the stamp (S2200), the stamp SMP may press the protective layer (for example, the cover window CW) in one direction (for example, the direction opposite to the third direction DR3). The protective layer (for example, the cover window CW) may be hardened in the pressing with the stamp (S2800).

In some embodiments, one inclined surface mold ICN_m may be disposed in an area corresponding to one sub-pixel. In some embodiments, one inclined surface mold ICN_m may be disposed in an area corresponding to two or more sub-pixels SP (see FIG. 4). In some embodiments, one inclined surface mold ICN_m may be disposed in an area corresponding to one pixel PXL (see FIG. 4). In some embodiments, one inclined surface mold ICN_m may be disposed in an area corresponding to two or more pixels PXL.

In the detaching of the stamp SMP (S2900), the stamp SMP may be detached from the protective layer (for example, the cover window CW). The inclined surface ICN corresponding to the inclined surface mold ICN_m may be formed on the protective layer (for example, the cover window CW).

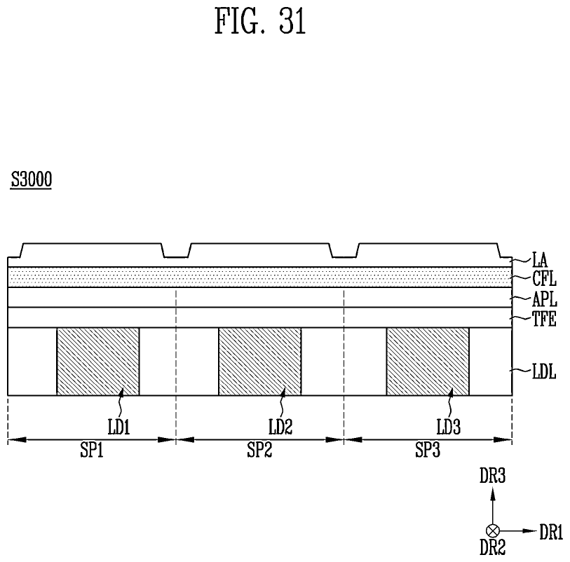

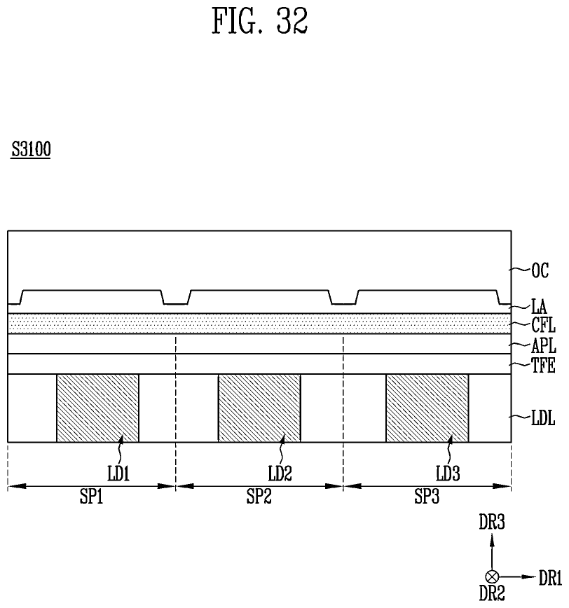

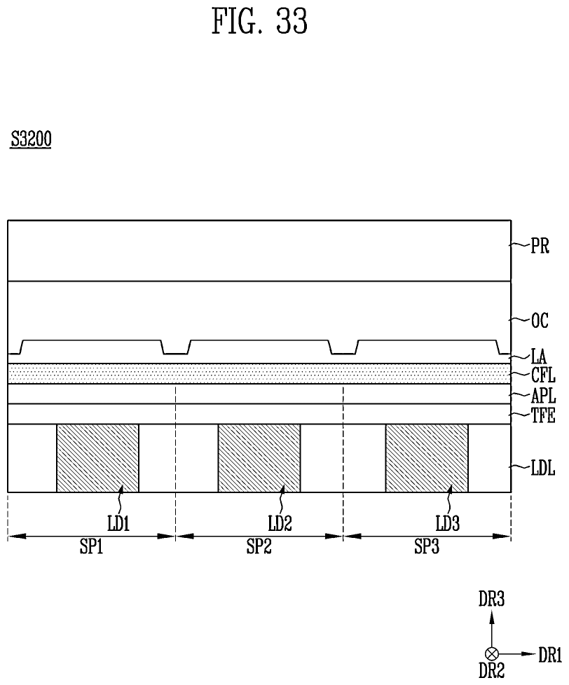

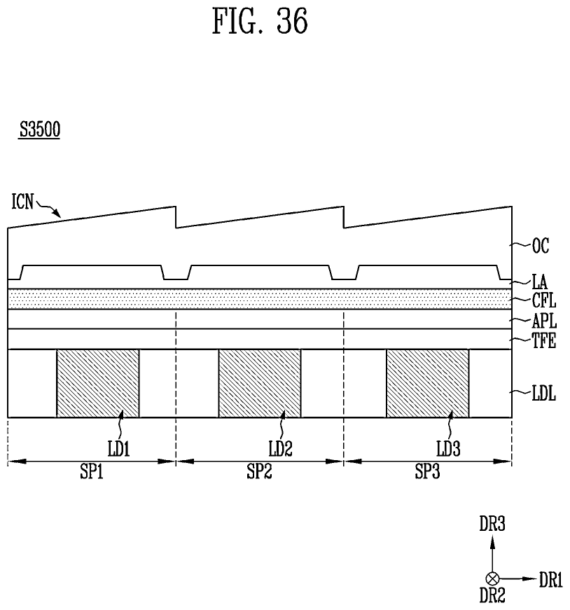

FIGS. 31 to 37 are other drawings for explaining a manufacturing method of a display panel according to an embodiment of the present disclosure.

Referring to FIGS. 31 to 37, the manufacturing method of the display panel according to the embodiments of the present disclosure includes preparing a lower substrate (S3000), forming an overcoat layer OC (S3100), forming a photoresist PR (S3200), pressing with a stamp (S3300), etching the photoresist PR and a protective layer to form an inclined surface (S3400), forming an inclined surface (S3500), and forming a cover window (S3600).

In the preparing of the lower substrate (S3000), the light emitting element layer LDL, the thin film encapsulation layer TFE, the adhesive layer APL, the color filter layer CFL, and the lens array LA may be sequentially formed on the substrate. The lower substrate may be configured to be the same as or similar to the lower substrate 1410 described in FIGS. 14B to 14E, FIGS. 20B and 20C.

In the forming of the overcoat layer OC (S3100), the overcoat layer OC may be disposed on the lower substrate. For example, in an embodiment in which the overcoat layer OC includes an epoxy resin, the epoxy resin may be applied on the lens array LA in the forming of the overcoat layer OC (S3100).

In the forming of the photoresist PR (S3200), the photoresist PR may be applied on the overcoat layer OC. The photoresist PR may include chemical materials whose characteristics change in response to light.

In the pressing with the stamp (S3300), a stamp SMP may be prepared. The stamp SMP may include an inclined surface mold ICN_m. In the pressing with the stamp (S3300), the stamp SMP may press the photoresist PR in one direction (for example, the direction opposite to the third direction DR3).

In some embodiments, one inclined surface mold ICN_m may be disposed in an area corresponding to one sub-pixel SP (see FIG. 4). In some embodiments, one inclined surface mold ICN_m may be disposed in an area corresponding to two or more sub-pixels SP. In some embodiments, one inclined surface mold ICN_m may be disposed in an area corresponding to one pixel PXL. In some embodiments, one inclined surface mold ICN_m may be disposed in an area corresponding to two or more pixels PXL.

In the etching of the photoresist PR and the protective layer to form an inclined surface (S3400), at least a portion of the photoresist PR and the protective layer (for example, the overcoat layer OC) may be etched by an etching machine ETC to form an inclined surface. The photoresist PR removed by the etching machine ETC may have the inclined surface ICN corresponding to the inclined surface mold ICN_m. In some embodiments, the photoresist PR may be completely removed by the etching machine ETC, but the embodiments of the present disclosure are not limited thereto.

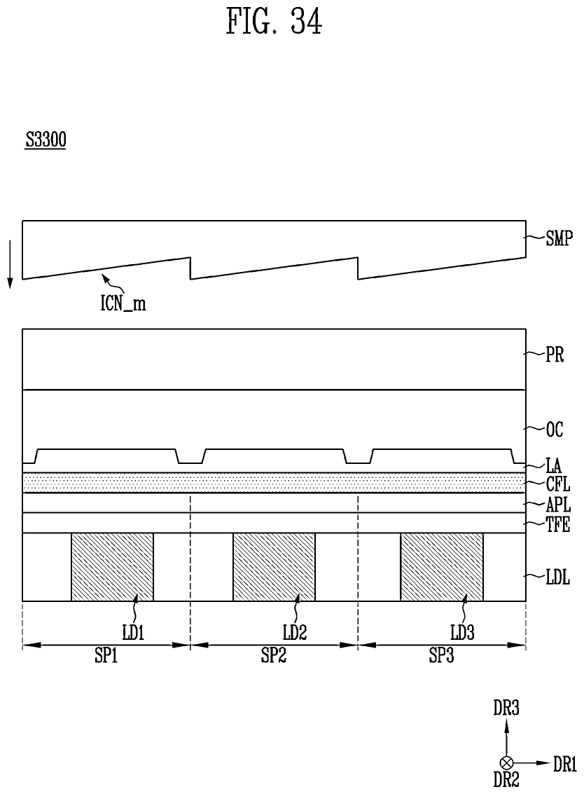

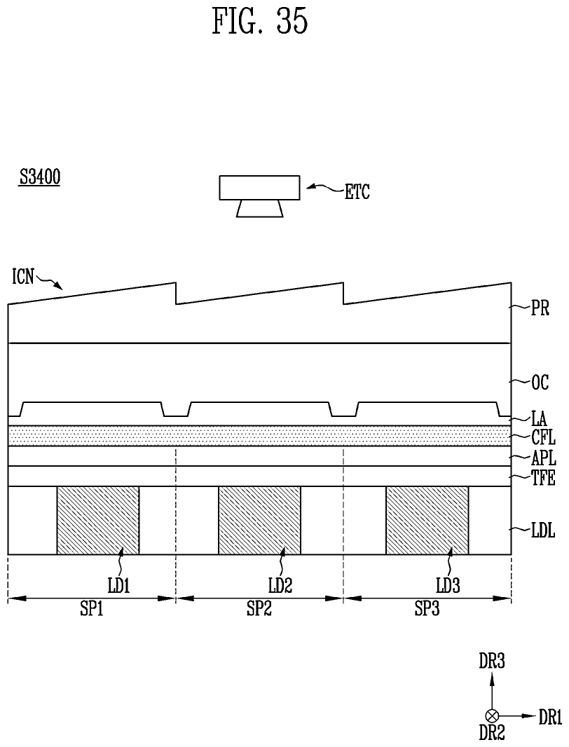

In the forming of the inclined surface (S3500), the photoresist PR and portions of the overcoat layer OC may be removed to form an inclined surface ICN. The inclined surface ICN corresponding to the above-described inclined surface mold ICN_m (see FIG. 34) may be formed on the overcoat layer OC. The inclined surface ICN may be formed by removing at least a portion of the overcoat layer OC by the etching machine ETC (see FIG. 35).

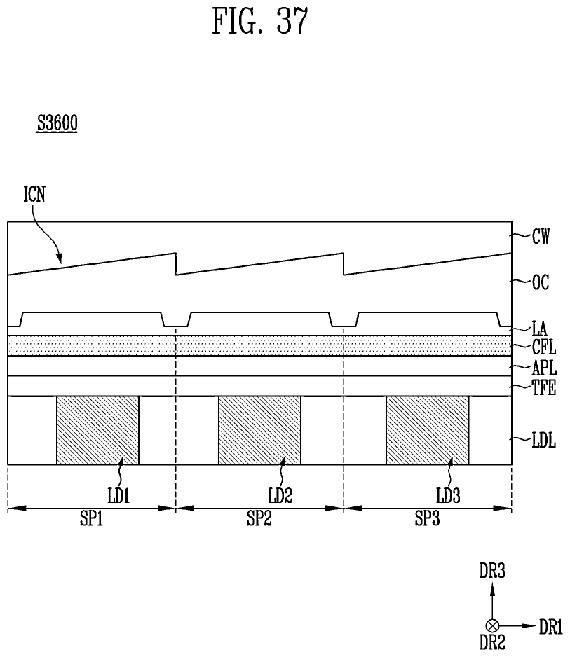

In the forming of the cover window (S3600), the cover window CW may be formed on the overcoat layer OC. Referring to FIG. 37, in the forming of the cover window (S3600), the cover window CW may be formed on the overcoat layer OC on which the inclined surface ICN is formed. For example, in an embodiment in which the cover window CW includes glass, the cover window CW may be formed on the overcoat layer OC in such a way that glass including the inclined surface ICN on the lower surface is disposed on the overcoat layer OC.

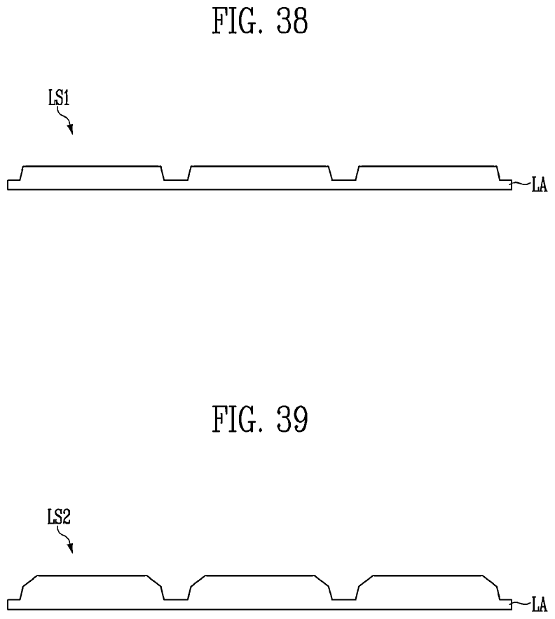

FIGS. 38 to 40 illustrate the lens arrays LA according to the embodiments of the present disclosure.

Referring to FIGS. 38 to 40, various embodiments of a shape of the lens array LA according to the embodiments of the present disclosure are illustrated.

Referring to FIG. 38, the lens array LA according to the embodiments of the present disclosure may include a first lens LS1. The first lens LS1 may have a quadrangular shape (for example, a trapezoidal shape). The first lens LS1 may have a shape that becomes narrower toward the thickness direction. The first lens LS1 may have a flat upper surface.

Referring to FIG. 39, the lens array LA according to the embodiments of the present disclosure may include a second lens LS2. The second lens LS2 may be configured to have a polygonal shape including two or more tapered inclined surfaces on its sides. For example, the second lens LS2 may have a polygonal (for example, hexagonal) shape other than a quadrangular shape. The second lens LS2 may have a flat upper surface.

Referring to FIG. 41, the lens array LA according to the embodiments of the present disclosure may include a third lens LS3. The third lens LS3 may have a semicircular shape or a water drop shape. The third lens LS3 may have a curved upper surface.

However, the shapes of the lens array LA according to the embodiments of the present disclosure are not limited to the above, and the shapes of the lens array LA presented through FIG. 38 to FIG. 40 are only examples.

FIG. 41 illustrates an example of a display system 4000 according to embodiments of the present disclosure.

Referring to FIG. 41, the display system 4000 may include a processor 4010 and one or more display devices 4020 and 4030.

The processor 4010 can perform various tasks and calculations. In embodiments, the processor 4010 may include an application processor (AP), a graphics processing unit (GPU), a microprocessor, a central processing unit (CPU), and the like. The processor 4010 may be connected to and control other constituent elements of the display system 4000 through a bus system.

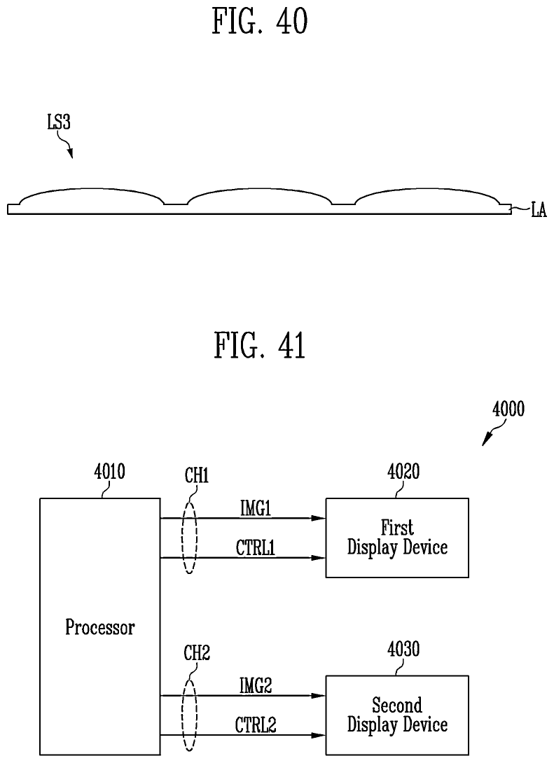

In FIG. 40, the display system 4000 is shown to include the first and second display devices 4020 and 4030. The processor 4010 may be connected to the first display device 4020 through a first channel CH1 and to the second display device 4030 through a second channel CH2.

Through the first channel CH1, the processor 4010 may transmit first image data IMG1 and a first control signal CTRL1 to the first display device 4020. The first display device 4020 may display an image based on the first image data IMG1 and the first control signal CTRL1. The first display device 4020 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 4010 may transmit second image data IMG2 and a second control signal CTRL2 to the second display device 4030. The second display device 4030 may display an image based on the second image data IMG2 and the second control signal CTRL2. The second display device 4030 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 4000 may include a computing system providing image display functions such as a portable computer, a mobile phone, a smart phone, a tablet personal computer (PC), a smart watch, a watch phone, a portable multimedia player (PMP), a navigation system, and an ultra-mobile personal computer (UMPC). In addition, the display system 4000 may include at least one of a head-mounted display device (HMD), a virtual reality (VR) device, a mixed reality (MR) device, and an augmented reality (AR) device.

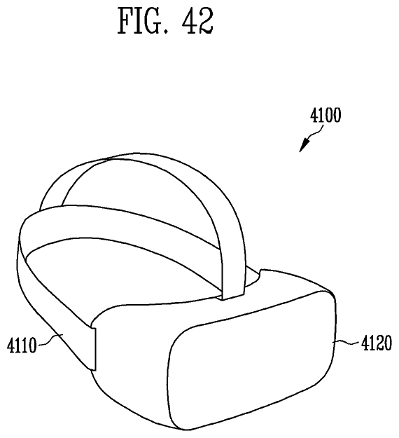

FIG. 42 illustrates a perspective view of an application example of the display system 4000 of FIG. 41.

Referring to FIG. 42, the display system 4000 of FIG. 41 may be applied to a head-mounted display device 4100. The head-mounted display device 4100 may be a wearable electronic device that may be worn on the user's head.

The head-mounted display device 4100 may include a head-mounted band 4110 and a display device accommodation case 4120. The head-mounted band 4110 may be connected to the display device accommodation case 4120. The head-mounted band 4110 may include a horizontal band and/or a vertical band for fixing the head-mounted display device 4100 to the user's head. The horizontal band may be configured to surround the side portion of the user's head, and the vertical band may be configured to surround the upper portion of the user's head. However, embodiments are not limited thereto. For example, the head-mounted band 4110 may be implemented in the form of a spectacle frame, a helmet, or the like.

The display device accommodation case 4120 may accommodate the first and second display devices 4020 and 4030 of FIG. 41. The display device accommodation case 4120 may further accommodate the processor 4010 of FIG. 41.

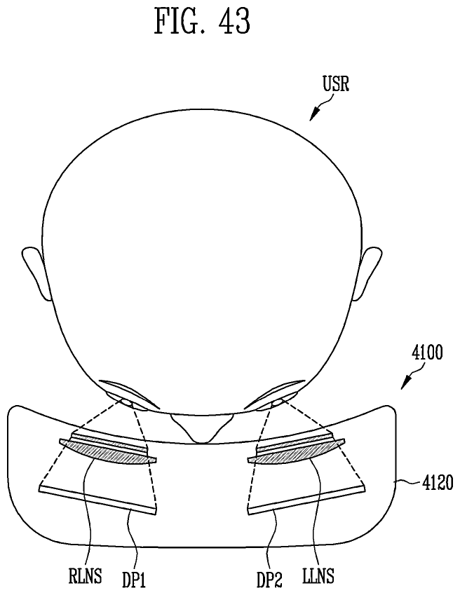

FIG. 43 illustrates the head-mounted display device 4100 worn on the user USR.

Referring to FIG. 43, a first display panel DP1 of the first display device 4020 (see FIG. 41) and a second display panel DP2 of the second display device 4030 (see FIG. 41) may be disposed in the head-mounted display device 4100. The head-mounted display device 4100 may further include one or more lenses. For example, the head-mounted display device 4100 may include a left eye lens LLNS and a right eye lens RLNS.

In the display device accommodation case 4120, the right eye lens RLNS may be disposed between the first display panel DP1 and the right eye of the user USR. In the display device accommodation case 4120, the left eye lens LLNS may be disposed between the second display panel DP2 and the left eye of the user USR.

An image outputted from the first display panel DP1 may be viewed to the right eye of the user USR through the right eye lens RLNS. The right eye lens RLNS may refract light emitted from the first display panel DP1 to be directed to the right eye of the user USR. The right eye lens RLNS may perform an optical function to adjust the viewing distance between the first display panel DP1 and the right eye of the user USR.

An image outputted from the second display panel DP2 may be viewed to the left eye of the user USR through the left eye lens LLNS. The left eye lens LLNS may refract light emitted from the second display panel DP2 to be directed to the left eye of the user USR. The left eye lens LLNS may perform an optical function to adjust the viewing distance between the second display panel DP2 and the left eye of the user USR.

In embodiments, each of the right eye lens RLNS and the left eye lens LLNS may include an optical lens having a cross-section of a pancake shape. In embodiments, each of the right eye lens RLNS and the left eye lens LLNS may include a multi-channel lens including sub-areas with different optical characteristics. In the above embodiment, each of the first and second display panels DP1 and DP2 may output images corresponding to the sub-areas of the multi-channel lens, and each of the outputted images may pass through the corresponding sub-areas to be viewed to the user USR.

The right eye lens RLNS may be implemented by applying the external lens 810 (see FIG. 8) described above. The left eye lens LLNS may be implemented by applying the external lens 810 (see FIG. 8) described above.

Referring further to the above-mentioned FIG. 8, light emitted from the central area of the first display panel DP1 may be incident in the central area of the right eye lens RLNS. Light emitted from the peripheral area (for example, edge area) of the first display panel DP1 may be incident in the peripheral area (for example, edge area) of the right eye lens RLNS. Light emitted from the central area of the second display panel DP2 may be incident in the central area of the left eye lens LLNS. Light emitted from the peripheral area (for example, edge area) of the second display panel DP2 may be incident in the peripheral area (for example, edge area) of the left eye lens LLNS.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims. Therefore, those skilled in the art will understand that various modifications and other equivalent embodiments of the present disclosure are possible. Consequently, the true technical protective scope of the present disclosure must be determined based on the technical spirit of the appended claims.

What is claimed is:

1. A display panel comprising:
a substrate;
a pixel circuit layer disposed on the substrate and including at least one switching element and at least one storage element;
a light emitting element layer including a plurality of light emitting elements electrically connected to the pixel circuit layer and disposed on the pixel circuit layer;
an overcoat layer disposed on the light emitting element layer and having a first refractive index; and
a cover window disposed on the overcoat layer and having a second refractive index greater than the first refractive index,
wherein at least one of the overcoat layer and the cover window includes a plurality of inclined surfaces, and
wherein inclination angles of the plurality of inclined surfaces in a central area are different from those in an edge area.

2. The display panel of claim 1, wherein the inclination angle in the central area is smallest and the inclination angle in the edge area is largest.

3. The display panel of claim 2, wherein light emitted from a light emitting element in the central area is emitted in a normal direction to the substrate, and
wherein light emitted from a light emitting element in the edge area is emitted in an outer direction of the substrate to form a predetermined angle with the normal direction of the substrate.

4. The display panel of claim 1, wherein the overcoat layer includes the plurality of inclined surfaces, and
wherein heights of the plurality of inclined surfaces increase as distances from the central area increase.

5. The display panel of claim 1, wherein the cover window includes the plurality of inclined surfaces, and
wherein heights of the plurality of inclined surfaces increase as distances from the central area increase.

6. The display panel of claim 1, wherein each of the plurality of inclined surfaces is disposed in an area corresponding to one light emitting element.

7. The display panel of claim 1, wherein the light emitting element layer includes at least two light emitting elements, and
wherein each of the plurality of inclined surfaces is disposed in an area corresponding to the at least two light emitting elements.

8. The display panel of claim 1, wherein some of the plurality of inclined surfaces are shifted from corresponding light emitting elements in an outer direction of the substrate.

9. The display panel of claim 8, further comprising:
an optical functional layer disposed between the light emitting element layer and the overcoat layer,
wherein the optical functional layer includes:
a color filter layer including a color filter configured to filter a wavelength band of light emitted from the light emitting element, and
a lens array including a plurality of lenses, and
wherein the optical functional layer is shifted from the corresponding light emitting elements in the outer direction of the substrate.

10. The display panel of claim 1, wherein the overcoat layer includes an epoxy resin whose refractive index is the first refractive index and the cover window includes glass whose refractive index is the second refractive index, and
wherein the first refractive index is 1.2 to 1.4 and the second refractive index is 1.5 to 1.9.

11. A manufacturing method of a display panel, comprising:
preparing a lower substrate;
forming an overcoat layer on the lower substrate;
pressing the lower substrate on which the overcoat layer is formed with a stamp including a plurality of inclined surface molds;
detaching the stamp from the lower substrate; and
forming a cover window on the overcoat layer.

12. The manufacturing method of the display panel of claim 11, wherein the stamp presses an upper surface of the overcoat layer in the pressing with the stamp, and
wherein a plurality of inclined surfaces are formed on the overcoat layer in the pressing with the stamp.

13. The manufacturing method of the display panel of claim 12, wherein glass having a lower surface with a plurality of inclined surfaces corresponding to the plurality of inclined surfaces of the overcoat layer is disposed on the overcoat layer in the forming of the cover window.

14. The manufacturing method of the display panel of claim 11, further comprising:
applying a photoresist on the overcoat layer,
wherein the stamp presses the applied photoresist in the pressing with the stamp, and
wherein a plurality of inclined surfaces corresponding to the plurality of inclined surface molds are formed in the photoresist.

15. The manufacturing method of the display panel of claim 14, further comprising:
etching the photoresist and the overcoat layer on which the plurality of inclined surfaces are formed,
wherein the plurality of inclined surfaces corresponding to the plurality of inclined surface molds are formed on the overcoat layer in the etching of the photoresist and the overcoat layer.

16. The manufacturing method of the display panel of claim 11, wherein a pixel circuit layer, a light emitting element layer, a thin film encapsulation layer, an adhesive layer, a color filter layer, and a lens array are sequentially formed on the lower substrate in the preparing of the lower substrate.

17. A head-mounted display device, comprising:
a first display panel disposed in a display device accommodation case and having a protective layer disposed on an uppermost layer of the first display panel and including a plurality of inclined surfaces;
a right eye lens disposed in the display device accommodation case and configured to refract light refracted on the plurality of inclined surfaces of the first display panel to be directed to a right eye of a user;
a second display panel disposed in the display device accommodation case to be spaced apart from the first display panel and having a protective layer disposed on an uppermost layer of the second display panel and including a plurality of inclined surfaces; and
a left eye lens disposed in the display device accommodation case and configured to refract light refracted on the plurality of inclined surfaces of the second display panel to be directed to a left eye of the user.

18. The head-mounted display device of claim 17, wherein light emitted from a central area of the first display panel is incident in a central area of the right eye lens and light emitted from an edge area of the first display panel is incident in an edge area of the right eye lens, and
light emitted from a central area of the second display panel is incident in a central area of the left eye lens and light emitted from an edge area of the second display panel is incident in an edge area of the left eye lens.

19. The head-mounted display device of claim 17, wherein each of the first display panel and the second display panel includes:
a substrate;
a pixel circuit layer disposed on the substrate and including at least one switching element and at least one storage element;
a light emitting element layer including a plurality of light emitting elements electrically connected to the pixel circuit layer and disposed on the pixel circuit layer;
an overcoat layer disposed on the light emitting element layer and having a first refractive index; and
a cover window disposed on the overcoat layer and having a second refractive index greater than the first refractive index,
wherein at least one of the overcoat layer and the cover window includes a plurality of inclined surfaces, and
wherein inclination angles of the plurality of inclined surfaces in a central area are different from those in an edge area.

20. The head-mounted display device of claim 19, wherein the inclination angles of the plurality of inclined surfaces increase as distances from the central area increase.
